(19) United States
(12) Patent Application Publication
(10) Pub. No.: US 2026/0123003 A1
(43) Pub. Date: Apr. 30, 2026

(54) METHOD OF MANUFACTURING AN ELECTRONIC DEVICE, AND CORRESPONDING ELECTRONIC DEVICE

(71) Applicant: STMicroelectronics International N.V., Geneva (CH)

(72) Inventor: Olivier WEBER, Grenoble (FR)

(73) Assignee: STMicroelectronics International N.V., Geneva (CH)

(21) Appl. No.: 19/360,357

(22) Filed: Oct. 16, 2025

(30) Foreign Application Priority Data
Oct. 29, 2024 (FR) FR2411824

(51) Int. Cl. H10D 64/01; H10D 84/01; H10D 84/83

(52) U.S. Cl. CPC H10D 64/021; H10D 64/017; H10D 84/0158; H10D 84/834

(57) ABSTRACT

The present description concerns a method of manufacturing, inside and on top of a semiconductor substrate, an electronic device comprising first FinFET transistors in a first region, and a second MOSFET transistor in a second region, the method comprising: the forming, in the first region, of first sacrificial gates of a first length along a first fin of the semiconductor substrate, and, in the second region, of a second sacrificial gate of a second length greater than the first length on the semiconductor substrate, including the forming of first spacers of a first thickness on the flanks of the first sacrificial gates, and of second spacers of a second thickness greater than the first thickness on the flanks of the second sacrificial gate; the forming, in the semiconductor substrate, of first semiconductor regions on either side of the first sacrificial gates flanked by the first spacers; the forming, in the semiconductor substrate, of second semiconductor regions on either side of the second sacrificial gate flanked by the second spacers; and the replacing of each first sacrificial gate by a first gate structure and of the second sacrificial gate by a second gate structure.

### CROSS-REFERENCE TO PRIORITY APPLICATION

This application claims the priority benefit of French patent application number FR2411824, filed on October 29, 2024, entitled “Procédé de fabrication d’un dispositif électronique, et dispositif électronique associé”, which is hereby incorporated by reference to the maximum extent allowable by law.

### BACKGROUND

### Technical Field

The present disclosure generally concerns electronic devices, and in particular the manufacturing of electronic devices.

The present disclosure particularly concerns the manufacturing of an electronic device comprising one (or a plurality of) metal-oxide-semiconductor field-effect transistor(s) (MOSFET), for example a high-voltage MOSFET, co-integrated with one (or a plurality of) fin field-effect transistor(s) (FinFET).

### Description of the Related Art

During the manufacturing of an electronic device comprising different electronic components inside and on top of the same semiconductor substrate, a manufacturer may want to use the same manufacturing method for all or part of the electronic components, in particular for reasons of manufacturing cost. For example, the electronic components of the electronic device may be manufactured on a same production line. However, if the manufacturing method is entirely implemented on the entire semiconductor substrate, with no separate treatment such as the fact of providing protections, such as masks, any implemented treatment applies to all the electronic components. However, a treatment used to form one electronic component may not be suitable for another electronic component, and it is generally necessary to provide protections, such as masks, so that certain treatments do not apply to all electronic components.

Depending on the electronic device to be manufactured, and in particular depending on the different electronic components to be formed inside and on top of the same semiconductor substrate, it may be complicated, or even impossible, to manufacture the different electronic components on the same production line. For example, it may be necessary to implement specific technological steps to form a MOSFET transistor, for example a high-voltage MOSFET transistor, in a FinFET-type transistor manufacturing technology. The considered voltage is the maximum voltage that can be applied to a transistor, without risking damaging it, a high voltage being a voltage typically higher than 3 Volts.

Further, the use of a number of protective masks which is as small as possible is generally desired.

### BRIEF SUMMARY

There exists a use for at least partly improving certain aspects of known electronic devices, and of known electronic device manufacturing methods.

An embodiment overcomes all or part of the disadvantages of known electronic devices, and of known electronic device manufacturing methods.

An embodiment provides a method of manufacturing, inside and on top of a semiconductor substrate, an electronic device comprising first fin field-effect transistors in a first region, and at least one second field-effect transistor with a metal-oxide-semiconductor structure in at least one second region, the method comprising:

the forming, in the first region, of first sacrificial gates, of a first length, along a first fin of the semiconductor substrate, said first fin having a first width at a first surface of the semiconductor substrate and being isolated by first trenches in the semiconductor substrate, and, in each second region, of a second sacrificial gate, of a second length greater than the first length, on the first surface of the semiconductor substrate, the first and second sacrificial gates being made of a sacrificial material; the forming of the first and second sacrificial gates comprising the forming of first spacers of a first thickness on the flanks of the first sacrificial gates, and of second spacers of a second thickness greater than the first thickness on the flanks of the second sacrificial gate;

the forming, in the semiconductor substrate, of first semiconductor regions in the first region on either side of the first sacrificial gates flanked by the first spacers, forming drain and source regions of the first transistors;

the forming, in the semiconductor substrate, of second semiconductor regions in each second region on either side of the second sacrificial gate flanked by the second spacers, forming drain and source regions of the at least one second transistor; and

the replacing of each first sacrificial gate with a first gate structure and of each second sacrificial gate with a second gate structure.

According to an embodiment, the sacrificial material is a polysilicon.

According to an embodiment, the forming of the first and second sacrificial gates comprises:

the forming, on the semiconductor substrate, of a first portion of a first layer made of the sacrificial material in the first region, and of a second portion of the first layer in each second region, said first portion extending over substantially the entire length of the first region, and said second portion extending over the second length, shorter than the length of the second region, forming all or part of the second sacrificial gate;

the forming, on the flanks of the first and second portions of the first layer, of a stack of layers made of dielectric material;

the stack of layers made of dielectric material on the flanks of the second portion of the first layer forming all or part of the second spacers.

According to an embodiment, the forming of the stack of layers comprises:

the forming, on the flanks of the first portion of the first layer, respectively of the second portion of the first layer, and on the semiconductor substrate, of first L-shaped portions, respectively second L-shaped portions, of a second layer made of dielectric material, preferably made of a low permittivity material;

the forming, on the first L-shaped portions, respectively second L-shaped portions, of first D-shaped portions, respectively second D-shaped portions, of a third layer made of dielectric material, for example of a nitride, for example of a silicon nitride;

the forming, on the first D-shaped portions, respectively second D-shaped portions, of first portions, respectively second portions, of a fourth layer made of dielectric material, for example of a silicon nitride.

According to an embodiment, the forming of the first and second portions of the fourth layer comprises the deposition and then the etching of said fourth layer so as to form:

in the first region: the first portions and third portions of said fourth layer on the first portion of the first layer, said third portions being arranged in a row and each extending over a length substantially equal to the first length; and

in each second region: the second portions and a fourth portion of said fourth layer on the second portion of the first layer.

According to an embodiment, the method comprises the etching of the first portion of the first layer so as to form third portions of said first layer arranged in a row and each extending over a length substantially equal to the first length, forming all or part of the first sacrificial gates.

According to an embodiment, the etching of the first portion of the first layer is performed through the third portions of the fourth layer forming an etch mask, the third portions of the first layer extending between the semiconductor substrate and the third portions of the fourth layer.

According to an embodiment, the forming of the first and second spacers comprises, after the forming of the third portions of the first layer, the forming of first portions of a fifth layer of a dielectric material, preferably of low permittivity, on the flanks of the first sacrificial gates, forming the first spacers, and of second portions of said fifth layer on the flanks of each second sacrificial gate covered by the stack of layers, the second spacers including said second portions of said fifth layer.

According to an embodiment, the fifth layer comprises a fourth portion continuing the second portions of said fifth layer so as to cover the fourth portion of the fourth layer.

According to an embodiment, the forming of the second semiconductor regions is performed at the same time as the forming of the first semiconductor regions.

According to an embodiment, the forming of the second semiconductor regions is performed before or after the forming of the first semiconductor regions.

According to an embodiment, the fifth layer comprises a third portion extending on either side of the second sacrificial gate and of the second spacers in each second region, so as to mask the semiconductor substrate in said second region during the forming of the first semiconductor regions.

According to an embodiment, the forming of the first semiconductor regions, and optionally of the second semiconductor regions, comprises the forming of cavities in the semiconductor substrate from the first surface, and then the filling of said cavities by epitaxy and implantation of dopant atoms.

An embodiment provides an electronic device comprising, inside and on top of a semiconductor substrate, first fin field-effect transistors in a first region and at least one second field-effect transistor with a metal-oxide-semiconductor structure in at least one second region;

the first transistors each comprising a first gate structure of a first length along a first fin of the semiconductor substrate, said first fin having a first width at a first surface of the semiconductor substrate and being isolated by first trenches in the semiconductor substrate, each first gate structure being flanked by a first spacer having a first thickness;

each second transistor comprising a second gate structure of a second length on the first surface of the semiconductor substrate, the second length being greater than the first length, each second gate structure being flanked by a second spacer having a second thickness greater than the first thickness.

According to an embodiment, a third transistor of the at least one second transistor is formed on top and inside of a mesa flush with the first surface of the semiconductor substrate, in a third region of the at least one second region.

According to an embodiment, a fourth transistor of the at least one second transistor is formed along a second fin of the semiconductor substrate, in a fourth region of the at least one second region, the second fin having a second width at the first surface of the semiconductor substrate, and being isolated by second trenches in the semiconductor substrate, the second width being greater than the first width; for example:

the second width is at least twice greater than the first width; and/or

the first width is smaller than 15 nm, for example smaller than or equal to 10 nm; and/or

the second width is greater than 20 nm, for example greater than or equal to 30 nm.

According to an embodiment, a plurality of second transistors are formed in a plurality of second regions;

a third transistor of the at least one second transistor being formed, in a third region of the at least one second region, on top and inside of a mesa flush with the first surface of the semiconductor substrate; and

a fourth transistor of the at least one second transistor being formed, in a fourth region of the at least one second region, on top and inside of a second fin flush with the first surface of the semiconductor substrate and isolated by second trenches in the semiconductor substrate, the second fin having a second width greater than the first width, for example at least twice greater than or equal to the first width.

According to an embodiment, the method comprises the forming of the first fin in the first region and of the second fin in the fourth region, the forming of said first and second fins comprising:

the forming, on the first surface of the semiconductor substrate, of first pillars in the first region and of second pillars in the fourth region, the first and second pillars being arranged side by side in a row, and being made of a first material, for example an amorphous silicon, the first pillars being separated from one another by a first distance, and the second pillars being separated from one another by a second distance;

the deposition, on the first and second pillars, of a sixth layer made of a second material, for example a silicon oxide, selectively etchable over the first material, the sixth layer having a third thickness on the flanks of the first and second pillars;

the removal of the sixth layer from the first region, said sixth layer being kept on the flanks of the second pillars in the fourth region;

the deposition, on the first and second pillars, of a seventh layer made of the second material, the seventh layer having a fourth thickness defined to form, on the flanks of the first pillars, first posts separated from one another between the first pillars;

the sixth and seventh layers forming, on the flanks of the second pillars, second posts, the third and fourth thicknesses being defined so that the second posts are joining between the second pillars, the joining second posts forming third posts coupling two adjacent second pillars; and

the removal, for example by etching, of the first and second pillars made of the first material;

the etching of the semiconductor substrate from the first surface through the first, second, and third posts made of the second material forming an etch mask;

the etching of the semiconductor substrate forming first trenches in the semiconductor substrate defining the first fin between the first trenches in the first region, and second trenches in the semiconductor substrate defining the second fin between the second trenches in the fourth region.

According to an embodiment, the fourth thickness is smaller than the third thickness.

According to an embodiment, the fourth thickness is smaller than half the first distance.

According to an embodiment, the third thickness is greater than or equal to half the second distance.

According to an embodiment, the first distance is substantially equal to the second distance.

According to an embodiment, the first thickness is smaller than or equal to 15 nm and the second thickness is greater than or equal to 30 nm.

According to an embodiment, the first length is smaller than or equal to 30 nm and the second length is greater than or equal to 150 nm.

An embodiment provides a method of manufacturing, inside and on top of a semiconductor substrate, at least one first fin for first fin field-effect transistors (FinFETs) in a first region of an electronic device and of at least one second fin for at least one second field-effect transistor with a metal-oxide-semiconductor structure (MOSFET) in a second region of the electronic device, the method comprising:

the forming, on a first surface of the semiconductor substrate, of first pillars in the first region and of second pillars in the second region, the first and second pillars being arranged side by side in a row, and being made of a first material, the first pillars being separated from one another by a first distance, and the second pillars being separated from one another by a second distance;

the deposition, on the first and second pillars, of a sixth layer made of a second material selectively etchable over the first material, the sixth layer having a third thickness on the flanks of the first and second pillars;

the removal of the sixth layer from the first region, the sixth layer being kept on the flanks of the second pillars in the second region;

the deposition, on the first and second pillars, of a seventh layer made of the second material, the seventh layer having a fourth thickness defined to form, on the flanks of the first pillars, first posts separated from one another between the first pillars;

the sixth and seventh layers forming, on the flanks of the second pillars, second posts, the third and fourth thicknesses being defined so that the second posts are joining between the second pillars, the joining second posts forming third posts coupling two adjacent second pillars; and

the removal, for example by etching, of the first and second posts;

the etching of the semiconductor substrate from the first surface through the first, second, and third posts forming an etch mask;

the etching of the semiconductor substrate forming first trenches in the semiconductor substrate defining the at least one first fin of a first width between the first trenches in the first region, and second trenches in the semiconductor substrate defining the at least one second fin of a second width between the second trenches in the second region, the second width being greater than the first width.

According to an embodiment, the second material is also selectively etchable over the semiconductor substrate.

According to an embodiment, the first material comprises, for example is, an amorphous silicon, and the second material comprises, for example is, an oxide, for example a silicon oxide.

According to an embodiment, the fourth thickness is smaller than the third thickness.

According to an embodiment, the fourth thickness is smaller than half the first distance.

According to an embodiment, the third thickness is greater than or equal to half the second distance.

According to an embodiment, the first distance is substantially equal to the second distance.

According to an embodiment, the first pillars are all arranged with a same first pitch, and the second pillars are all arranged with a same second pitch.

According to an embodiment, the first pitch is substantially equal to the second pitch.

According to an embodiment, the first distance, the first pitch, and the fourth thickness are determined so that the first posts are arranged with a same third pitch.

According to an embodiment, the third pitch is substantially equal to half the first pitch.

According to an embodiment, the second width is at least twice greater than or equal to the first width.

According to an embodiment, the first width is smaller than 15 nm, for example smaller than or equal to 10 nm, and the second width is greater than 20 nm, for example greater than or equal to 30 nm.

According to an embodiment, an eighth layer made of an oxide, for example, a silicon oxide, is arranged on the semiconductor substrate, a ninth layer made of a nitride, for example a silicon nitride, is arranged on the eighth layer, the first and second pillars being formed on the ninth layer, the eighth and ninth layers being for example, removed after the etching of the semiconductor substrate.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1 is a cross-section view, partial and simplified, of an example of an electronic device according to an embodiment;

FIG. 2, FIG. 3, FIG. 4, FIG. 5, FIG. 6, FIG. 7, FIG. 8, FIG. 9, FIG. 10, FIG. 11, FIG. 12, and FIG. 13 are cross-section or top views illustrating steps of a first example of a method of manufacturing an electronic device according to an embodiment;

FIG. 14, FIG. 15, FIG. 16, FIG. 17, FIG. 18, FIG. 19, FIG. 20, FIG. 21, FIG. 22, FIG. 23, FIG. 24, FIG. 25A, FIG. 25B, FIG. 26, FIG. 27, FIG. 28, FIG. 29, and FIG. 30 are cross-section or top views illustrating steps of a second example of a method of manufacturing an electronic device according to an embodiment, corresponding to the electronic device of FIG. 1; and

FIG. 31A and FIG. 31B are cross-section views, partial and simplified, of another example of an electronic device according to an embodiment.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, not all the steps of the manufacturing methods are detailed, the described embodiments being compatible with all or most electronic device manufacturing methods, in particular FinFET technology manufacturing methods, possibly subject to adaptations within the abilities of those skilled in the art on reading of the present disclosure.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

Throughout the description, the term “on” is used without distinction of the orientation in space of the element to which this term refers. For example, in the expression or characteristic “on a surface of a layer”, this surface is not necessarily oriented upwards, but may correspond to a surface oriented in any direction. For example, when a layer is deposited on an element, this means that it is deposited on all the exposed parts of the element at the time of the deposition of this layer. Further, the arrangement of a first element on a second element is to be understood as likely to correspond to the arrangement of the first element directly against the second element, with no intermediate element between the first and second elements, or as being likely to correspond to the arrangement of the first element on the second element with one or a plurality of intermediate elements between the first and second elements.

In the following description, the qualifiers “insulating” and “conductive” respectively signify, unless otherwise specified, electrically insulating and electrically conductive.

In the following description, when reference is made to a substrate, reference is made unless otherwise specified to a semiconductor substrate.

In the following description, a channel length of a transistor substantially corresponds to the distance between the source region and the drain region of the transistor. A gate length, or gate structure, is defined in the channel length direction.

In the following description, the term “fin” designates a projecting rib, usually elongated. The fin is made of the semiconductor material of the substrate and is delimited by trenches formed in the substrate on either side of the fin.

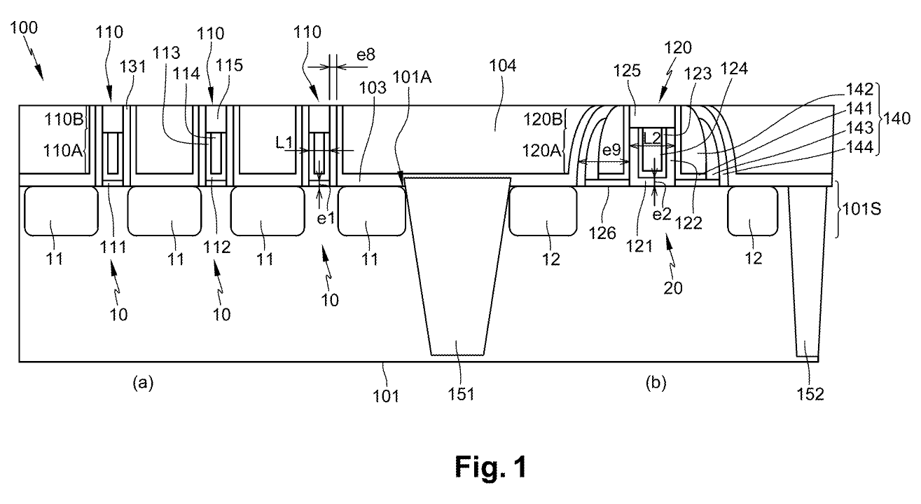

FIG. 1 is a cross-section view, partial and simplified, of an example of an electronic device 100 according to an embodiment.

The electronic device 100 of FIG. 1 is, for example, an electronic chip, or is a portion of an electronic chip.

Electronic device 100 comprises a semiconductor substrate 101. As an example, substrate 101 is made of silicon or based on silicon.

In FIG. 1, two regions (a) and (b) of electronic device 100, in which three FinFET transistors 10 and one MOSFET transistor 20 are respectively formed, are shown. FinFET transistors 10 are formed along a thin fin of semiconductor substrate 101. MOSFET transistor 20 may be formed on top and inside of an island, also referred to as a mesa, of semiconductor substrate 101, or on top and inside of a wide fin of semiconductor substrate 101, wider than the thin fin of FinFET transistors 10. Examples of fins and mesas are described later in the disclosure. The fins and the mesa are structures of semiconductor substrate 101 which are flush with the upper surface 101A of substrate 101, and are isolated by trenches formed in substrate 101 from upper surface 101A.

It will be understood that, in practice, region (a) may comprise a number of FinFET transistors different from three, and region (b) may comprise a number of MOSFET transistors greater than one. Further, electronic device 100 could include other electronic components, for example other transistors such as bipolar transistors, diodes, and/or resistors.

Region (a) is isolated from region (b) by an isolating trench 151, or isolating trenches 151. The MOSFET transistor is also isolated by another isolating trench 152 on the side opposite to region (a). Isolating trenches 151, 152 are, for example, shallow trench isolation (STI) trenches. Isolating trenches 151, 152 extend from the upper surface 101A of semiconductor substrate 101, or even slightly above upper surface 101A, into a layer 103 described hereafter.

In region (a), semiconductor regions 11 extend in substrate 101 on either side of gate structures 110. Similarly, in region (b), semiconductor regions 12 extend in substrate 101 on either side of a gate structure 120. Semiconductor regions 11 and 12 are for example epitaxial layers or regions, for example formed by epitaxy in cavities, for example shallow cavities or trenches, made in substrate 101 from upper surface 101A. Semiconductor regions 11 and 12 are flush with upper surface 101A and preferably extend down to a depth smaller, or even much smaller, than the thickness of substrate 101.

For example, at least an upper portion 101S of substrate 101, having a depth greater than or equal to the depth of semiconductor regions 11, 12, is doped with the first conductivity type or comprises doped wells of a first conductivity type, for example, type N, and semiconductor regions 11 and 12 are doped with the second conductivity type, for example, type P, to form P-type transistors (PMOS and PMOS FinFET). As an example, semiconductor regions 11 and 12 comprise germanium and boron atoms in the silicon (SiGeB).

In the rest of the disclosure, it is considered that the first conductivity type is type N, and that the second conductivity type is type P, although it could be the opposite, that is the first conductivity type of type P, and the second conductivity type of type N.

As a variant, semiconductor regions 11 and/or semiconductor regions 12 could be N-type doped, for example comprise phosphorus atoms in the silicon (SiP), to form N-type transistors (NMOS and FinFET NMOS), the wells in substrate 101 would then be adapted accordingly, depending in particular on the conductivity type of substrate 101.

Those skilled in the art may consider forming N-type FinFET transistors inside and on top of another thin fin, and/or NMOS transistors inside and on top of semiconductor substrate 101 (wide fin or mesa). More widely, electronic device 100 could comprise PMOS FinFET transistors and/or NMOS FinFET transistors co-integrated with PMOS MOSFET transistors and/or NMOS MOSFET transistors, the MOSFET transistors being arranged on top and inside of a mesa of semiconductor substrate 101 and/or on top of and inside of a wide fin of semiconductor substrate 101.

Semiconductor regions 11 correspond to the source and drain regions of FinFET transistors 10. In such a structure, the drain of one FinFET transistor corresponds to the source of the neighboring FinFET transistor, and/or conversely the source of one FinFET transistor corresponds to the drain of the neighboring FinFET transistor.

Semiconductor regions 12 correspond to the source and drain regions of MOSFET transistor 20.

Each gate structure 110, 120 is positioned on the upper surface 101A of substrate 101, while being generally insulated from the substrate by a gate insulator layer, or gate insulator 111, 121. The gate insulator is, for example, a silicon oxide, such as SiO₂, or a nitrided oxide (SiON).

In region (b), gate insulator 121 also covers the side walls of gate structure 120 over at least a partial height thereof, corresponding to the lower portion 120A described hereabove. Further, the gate insulator 121 of MOSFET 20 has a thickness e2 which is greater than the thickness e1 of the gate insulator 111 of FinFET transistors 10, for example at least twice as great. This enables to have a high-voltage MOSFET transistor, or HV transistor, in region (b). HV transistor 20, for example, operates at at least 3.3 Volts (V). FinFET transistors 10 generally operate at a voltage smaller than approximately 1 V.

For example, thickness e2 is in the range from 5 to 8 nm, for example equal to approximately 6.5 nm (corresponding to a GO2, “Gate Oxide 2” transistor), and thickness e1 is in the range from 0.6 to 1.5 nm, for example equal to approximately 0.8 nm (corresponding to a GO1, “Gate Oxide 1” transistor).

Each gate structure 110, 120 comprises a layer, or a multi-layer structure, generally comprising at least one metallic material, for example a titanium nitride (TiN), a tantalum nitride (TaN), and/or tungsten (W).

For example, each gate structure 110, 120 comprises a lower portion 110A, 120A comprising:

a layer 112, 122 of a material of high permittivity or dielectric constant (high-k), for example a hafnium oxide (HfO₂), at the bottom on gate insulator layer 111, 121, and on the side walls of gate structure 110, 120;

a layer 113, 123 made of a metallic material, for example of titanium nitride (TiN), on layer 112, 122; and

a layer 114, 124 made of a metallic material different from that of layer 113, 123, for example of tungsten (W), on layer 113, 123.

It is reminded that a high-permittivity material, or high-k material, is a material with a dielectric constant greater than that of silicon dioxide.

In region (a), high-k layer 112 directly covers the side walls of each gate structure 110, while in region (b), high-k layer 122 covers gate insulator 121 on the side walls of gate structure 120.

Layers 112, 122 and 113, 123 are, for example, U-shaped and layers 114, 124 each correspond to a filler layer that fills the space of gate structure 110, 120 not filled by the other layers.

In the shown example, each gate structure 110, 120 comprises an upper portion 110B, 120B on lower portion 110A, 120A, this upper portion comprising a silicon nitride layer 115, 125. This layer 115, 125 forms a protective layer, during an operation of removal of an oxide layer 104 described hereafter, to deposit a silicide contact layer on the drain and source regions.

This example of a gate structure is not limiting, and other gate structures may be considered by those skilled in the art.

The gate structure 120 of MOSFET 20 has a length L2 which is greater than the length L1 of the gate structure 110 of each FinFET 10. It is reminded that the length of a gate structure is taken in the direction of the channel length of the considered transistor, shown in FIG. 1.

For example, length L1 is smaller than or equal to 30 nm and length L2 is greater than or equal to 150 nm.

Layers 131, 141 made of a dielectric material are positioned on the flanks of each gate structure 110, 120, forming spacer layers, or spacers, on either side of gate structures 110, 120. Advantageously, the dielectric material of spacers 131, 141 is a material of low permittivity, or low dielectric constant (low-k), for example SiOCN, or SiBCN. When applied to spacers, a low-permittivity or low-k material is a material having a dielectric constant lower than that of silicon nitride, typically a permittivity lower than 7, but generally higher than that of silicon oxide, which is equal to approximately 3.9.

For example, spacers 131 have a thickness e8 (first thickness) in the range from 3 to 10 nm or smaller than 15 nm, and spacers 141 have a thickness in the range from 3 to 10 nm or smaller than 15 nm.

The thicknesses given for all spacers are taken at the upper surface 101A of substrate 101.

In region (a), spacers 131 are mainly on the sides of gate structures 110.

In region (b), gate insulator layer 121 comprises, or is coupled to, an insulating portion 126, for example a portion of oxide such as SiO₂, on either side of gate structure 120, and spacers 141 also extend over this insulating portion 126. Spacers 141 are thus L-shaped.

In region (b), each spacer 141 is part of a spacer structure 140 which comprises a plurality of other spacers made of dielectric material. There is thus a spacer structure 140 on each side of gate structure 120. In the shown example, each spacer structure 140 comprises, in addition to spacer 141:

a spacer 142 in the shape of half a D or of a triangle with a curved hypotenuse, referred to as D hereafter, positioned on L-shaped spacer 141;

a curved spacer 143 on spacer 142, following the curved shape of spacer 142: spacer 143 does not necessarily extend along the full height of spacer 142, and may extend over insulating portion 126; and

a curved spacer 144 on spacer 143, following the curved shape of spacer 143, and which does not extend over insulating portion 126.

For example, the materials of the various spacers of spacer structure 140 are not all the same.

For example, spacers 141 are made of a low-k material, spacers 142 are made of a nitride, for example a silicon nitride, spacers 143 are made of a silicon nitride, and spacers 144 are made of a low-k material.

For example, spacers 142 have a thickness in the range from 15 to 40 nm. For example, spacers 143 have a thickness in the range from 10 and 20 nm. For example, spacers 144 have a thickness in the range from 3 to 10 nm.

For example, spacer structure 140 has a thickness e9 (second thickness), taken at the upper surface 101A of substrate 101, in the range from 30 and 60 nm, or greater than 30 nm.

Thus, the spacer structure 140 of MOSFET transistor 20 has a thickness e9 much greater than the thickness e8 of the spacer 131 of FinFET transistors 10. This large thickness of the spacer structure 140 of MOSFET transistor 20 enables to space away the source and drain regions 12 from the gate 120 of MOSFET transistor 20, which enables to avoid a breakdown of this transistor in an operation at high voltage, typically higher than 3 V, so that MOSFET transistor 20 is adapted to operating at this high voltage. Indeed, the spacers condition in particular the spacing between the source and drain regions during the forming of these regions.

A layer 103 made of a dielectric material, for example a silicon nitride, covers the uncovered portions of the upper surface 101A of the substrate 101, as well as the flanks of gate structures 110 and 120 covered by spacers 131 and 140, following the shapes of these spacers.

An oxide layer 104, for example made of SiO₂, fills the spaces between the portions of the upper surface 101A covered by layer 103 and the flanks of gate structures 110 and 120 covered by spacers 131 and 140 and by layer 103. Thus, oxide layer 104 comprises a plurality of oxide portions within these spaces.

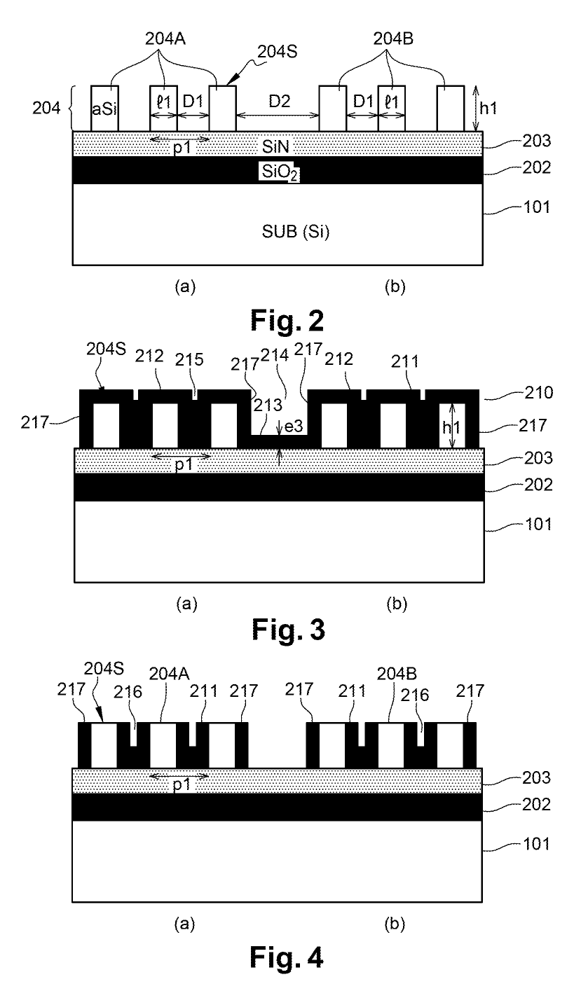

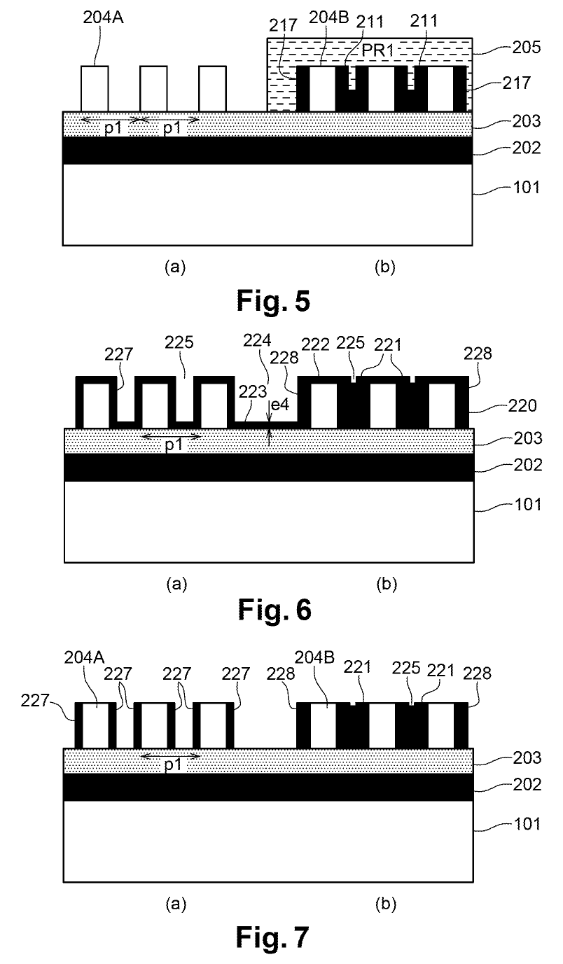

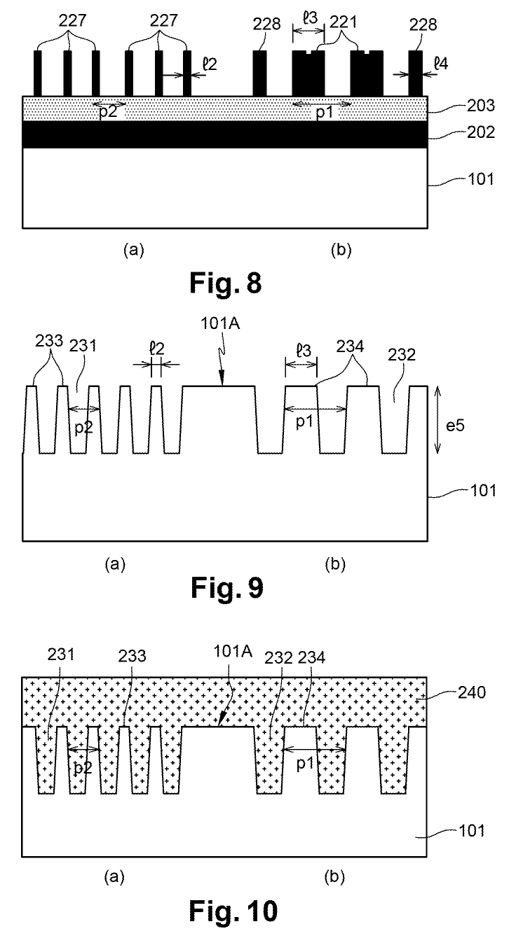

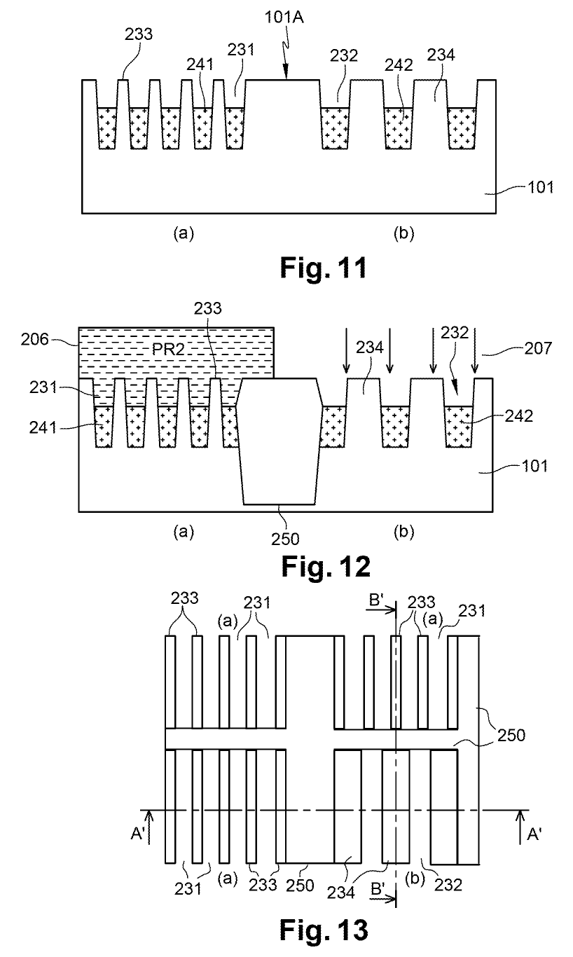

The following FIGS. 2 to 30 illustrate a plurality of examples of a method of manufacturing, in co-integrated fashion in a same electronic device, of FinFET transistors and of a MOSFET transistor, for example, but not necessarily, adjacent to the FinFET transistors.

In the following FIGS. 2 to 30, the first region a) of substrate 101 inside and on top of which the FinFET transistors are formed, and the second region b) of substrate 101 inside and on top of which the MOSFET transistor is formed, have been shown.

FIG. 2, FIG. 3, FIG. 4, FIG. 5, FIG. 6, FIG. 7, FIG. 8, FIG. 9, FIG. 10, FIG. 11, FIG. 12 and FIG. 13 are simplified cross-section or top views illustrating steps of a first example of a method of manufacturing an electronic device according to an embodiment.

The cross-section views of FIGS. 2 to 12 are obtained along the cross-section plane A′A′ shown in mixed lines in FIG. 13, which is a top view of FIG. 12 after the removal of an etch mask.

FIGS. 2 to 13 illustrate a first example of a first phase of the manufacturing method, which is then followed by a second phase, which may be similar to, or adapted from, the steps illustrated in FIGS. 20 to 30.

FIG. 2 shows, in a partial cross-section view, an initial structure comprising semiconductor substrate 101 (SUB(Si)).

A layer 202 of oxide, for example a silicon oxide (SiO₂), rests on substrate 101.

A protective (or etch stop) layer 203 made of dielectric material, for example of silicon nitride (SiN), rests on oxide layer 202.

As a variant, layer 202 may be a silicon nitride layer and layer 203 a silicon oxide layer. But in this case, the layers 210 and 220 described hereafter, which are deposited on layer 203 and the etching of which is selective over layer 203, are not made of silicon oxide, but are, for example, a silicon nitride. More generally, those skilled in the art will know how to adapt the materials of the layers, while respecting at least the etch selectivity criteria.

A plurality of pillars 204 (known as “mandrels”) are positioned on layer 203. Pillars 204 may be elongated in the direction perpendicular to FIG. 2, and may thus be in the form of beams. Pillars 204 are arranged in a row, that is, arranged side by side along a same direction.

In the example of FIG. 2, the pillars are made of amorphous silicon (aSi). The plurality of pillars comprises pillars 204A in region (a) and pillars 204B in region (b). In the example of FIG. 2, the width l1 and the pitch p1 of pillars 204 is substantially the same for all pillars 204A and 204B. In other words, the spacings D1, or distances D1, between two adjacent pillars 204A in region (a) are substantially equal to the distances D1 between two adjacent pillars 204B in region (b). This is not limiting, and for example, the distance between pillars 204A may be greater than the distance between pillars 204B. Further, the width of pillars 204A may be different from the width of pillars 204B. The pillars 204A and 204B located between the two regions (a) and (b) have a spacing D2 which is preferably greater than distance D1.

The pitch p1 of pillars 204 is for example in the range from 60 to 120 nm, for example equal to approximately 80 nm. The width l1 of pillars 204 is for example in the range from 20 and 40 nm, for example equal to approximately 30 nm.

Pillars 204 can be obtained by implementing a photolithography technique, for example by depositing an amorphous silicon layer on layer 203, and then an etch mask comprising patterns of crenellations and protrusions adapted to form pillars 204 (in particular adapted to the desired widths of the pillars and the desired distances between pillars), then by etching the amorphous silicon layer through the etch mask.

FIG. 3 illustrates, in a partial cross-section view, a structure obtained at the end of a step of deposition of a layer of oxide 210, for example of SiO₂, on the structure illustrated in FIG. 2.

Oxide layer 210 has a thickness e3 preferably adapted to filling the spaces between two adjacent pillars 204A in region (a) and two adjacent pillars 204B in region (b), over substantially the entire height h1 of pillars 204, forming portions between pillars (posts) 211. Thickness e3 is for example in the range from 15 to 30 nm, for example equal to approximately 20 nm for a pitch p1 of approximately 80 nm.

Oxide layer 210 further comprises substantially horizontal portions 212 on pillars 204A and 204B, a substantially horizontal portion 213 which covers layer 203 between the two regions (a) and (b), and substantially vertical portions (posts) 217 against the flanks of pillars 204A at the edges of the plurality of pillars 204A in region (a) and against the flanks of pillars 204B at the edges of the plurality of pillars 204B in region (b).

Oxide layer 210 follows the crenellated shape of the plurality of pillars 204. Thus, oxide layer 210 has a U-shaped portion 214 between the two regions (a) and (b), and may exhibit recesses 215, typically of a few nanometers, in the portions between pillars (posts) 211, recesses 215 extending substantially all the way to the level of the upper surface 204S of pillars 204. As a variant, there is no recess 215.

FIG. 4 illustrates, in a partial cross-section view, a structure obtained at the end of an etch step, preferably a dry etching, of oxide layer 210 so as to remove horizontal portions 212 and 213, while keeping the portions between pillars (posts) 211 (with recesses 216 which may be deeper than recesses 215 before etching, below the level of the upper surface 204S of pillars 204), and while leaving the vertical portions (posts) 217 in region (a) and in region (b).

The etching of FIG. 4 is preferably carried out across a thickness substantially equal to the thickness e3 of oxide layer 210. This etching may expose pillars 204A and 204B.

FIG. 5 illustrates, in a partial cross-section view, a structure obtained at the end:

of the forming of an etch mask 205 (PR1) covering the pillars 204B, the portions between pillars (posts) 211, and the vertical portions (posts) 217 in region (b), while leaving exposed the pillars 204A, the portions between pillars (posts) 211 and the vertical portions (posts) 217 in region (a); then

of an etch step to remove the portions between pillars (posts) 211 and the vertical portions (posts) 217 in region (a): a wet etching is used which enables to remove the oxide multidirectionally (isotropic etching), and this, selectively over the silicon of pillars 204A and the material (resin) of etch mask 205.

Etch mask 205 is then removed.

FIG. 6 illustrates, in a partial cross-section view, a structure obtained at the end of a step of deposition of another oxide layer 220, made of the same material as layer 210 of oxide, for example SiO₂, on the structure shown in FIG. 5.

Oxide layer 220 has a thickness e4 smaller than the thickness e3 of oxide layer 210, and such that it does not fill the spaces between two adjacent pillars 204A in region (a). Preferably, thickness e4 is smaller than half the distance D1 between two pillars 204A. Thickness e4 is, for example, in the range from 5 to 15 nm, for example equal to approximately 10 nm for a pitch p1 of approximately 80 nm.

Oxide layer 220 comprises substantially horizontal portions 222 on pillars 204A and 204B in regions (a) and (b), substantially vertical portions (posts) 227 against the flanks of pillars 204A in region (a), and forms, together with vertical portions (posts) 217, substantially vertical portions (posts) 228 against the flanks of the two pillars 204B at the edges of the plurality of pillars 204B in region (b). The adjacent vertical portions (posts) 227 in region (a) are separate from one another, that is, they are separated from one another by a non-zero distance. Between the two regions (a) and (b), oxide layer 220 comprises a substantially horizontal portion 223 which covers layer 203. The vertical portions (posts) 227 and 228 between the two regions (a) and (b) are also separate. In region (a), oxide layer 220 follows the crenellated shape of the plurality of pillars 204A, forming U-shaped portions 225 between two adjacent pillars 204A. Oxide layer 220 also comprises a U-shaped portion 224 between the two regions (a) and (b). In region (b), oxide layer 220 at least partially fills the recesses 216 in the portions between pillars (post) 221, thus being capable of forming recesses 225 having a depth substantially identical to that of recesses 215. As a variant, there is no recess 225. As a variant, the portions between pillars (post) 221 fill the spaces between two adjacent pillars 204B in region (b). For example, the portions between pillars (post) 221 correspond to the vertical portions (post) 228 which are joined together between two pillars 204B.

FIG. 7 illustrates, in a partial cross-section view, a structure obtained at the end of a step of etching, preferably a dry etching, of oxide layer 220 so as to remove horizontal portions 222 and 223, while keeping the portions between pillars (posts) 221 in region (b), the vertical portions (posts) 227 in region (a), and the vertical portions (posts) 228 in region (b). The etching of FIG. 7 is preferably carried out across a thickness substantially equal to the thickness e4 of oxide layer 220, so as to be able to expose pillars 204A and 204B.

FIG. 8 illustrates, in a partial cross-section view, a structure obtained at the end of a step of removal, by etching, of pillars 204A and 204B, leaving only the portions between pillars (posts) 221, vertical portions (posts) 227, and vertical portions (posts) 228 on layer 203. Preferably, a wet etching is used, which enables to remove the silicon of pillars 204A unidirectionally (anisotropic etching), and this, selectively over the silicon oxide of portions 221, 227, 228 and the silicon nitride of layer 203.

The portions between pillars (posts) 221 and the vertical portions (posts) 227 and 228 are generally elongated in the direction perpendicular to FIG. 8, in the form of beams.

The portions between pillars (posts) 221 in region (b) have a width l3 substantially equal to the distance D1 between two pillars 204B, and they have a pitch p1 substantially equal to the pitch between pillars 204B.

The vertical portions (posts) 227 in region (a) have a width l2 substantially equal to the thickness e4 of oxide layer 220, or even less due to the etching of FIG. 7. Vertical portions (posts) 227 have a width l2 smaller than half the distance D1 between two pillars 204A, and thus much lower than the width l3 of the portions between pillars (posts) 221. Further, since each pillar 204A has been replaced by two vertical portions (posts) 227, the vertical portions (posts) 227 have a pitch p2 much smaller than the pitch p1 between pillars 204A, for example approximately half the pitch p1. For example, for a pitch p1 substantially equal to 80 nm, a pitch p2 substantially equal to 40 nm can be obtained.

The values of distance D1, of width d1 of pillars 204, and of thickness e4 of oxide layer 220 may advantageously be defined so that the vertical portions (posts) 227 all have the same pitch p2.

The vertical portions (posts) 228 in region (b) have a width l4 which is substantially equal to, or probably lower than, due to the etchings of FIGS. 4 and 7, the cumulative thicknesses e3 and e4 of oxide layer 210 and of oxide layer 220.

The portions between pillars (posts) 221 and the vertical portions (posts) 227 and 228 will be used as an etch mask during an etching of semiconductor substrate 101 in the following step, so as to form fins separated by trenches in substrate 101, as explained in the following. Given that the vertical portions (posts) 227 in region (a) have a width l2 and a pitch p2 smaller than width l3 and than the pitch p1 respectively of the portions between pillars (posts) 221 in region (b), fins thinner and tighter in region (a) than in region (b) can be formed.

The portions between pillars (posts) 221 and the vertical portions (posts) 227 and 228 may be referred to as “fin spacers”.

The forming of such fin spacers of different widths and pitches in the two regions (a) and (b), and thus the forming of fins of different widths and pitches in the two regions (a) and (b), is made possible by the two steps of forming of oxide layers 210 and 220, with a thick oxide layer 210 to fill the spaces between pillars, this thick layer being removed from region (a), then another thin oxide layer 220 so as not to fill the spaces between pillars in region (a). As a variant, the gaps between pillars in region (b) could be filled by combining the thicknesses of the two oxide layers 210 and 220, and not necessarily only with oxide layer 210. Variant or not, once the pillars are removed, one obtains a pattern of thin, dense fin spacers in region (a) and a pattern of wider, less dense fin spacers in region (b). These fin spacers form the patterns of an etch mask intended to form the trenches and thus the fins, as described in the following.

FIG. 9 illustrates, in a partial cross-section view, a structure obtained at the end of a step of the etching of semiconductor substrate 101 through layers 203 and 202, which are also etched.

As indicated hereabove, this etching is performed through the etch mask formed by the portions between pillars (posts) 221 and the vertical portions (posts) 227 and 228.

To obtain the structure of FIG. 9 from FIG. 8, a mask which covers at least the central region between the two vertical portions (posts) 227 and 228 positioned opposite each other between regions (a) and (b) may be formed, so as not to etch substrate 101 between regions (a) and (b). This mask may encompass these two opposite vertical portions 227 and 228. The distance between regions (a) and (b) is generally greater than shown in the drawings. In other words, regions (a) and (b) are generally more distant from each other.

This etch step forms, in substrate 101, trenches 231 in region (a) and trenches 232 in region (b). Trenches 231, 232 extend from the upper surface 101A of substrate 101, down to a depth e5 smaller than the thickness of substrate 101.

The forming of trenches 231, 232 enables to define fins 233, 234 between trenches 231, 232. Fins 233, 234 correspond to the unetched portions of semiconductor substrate 101, protected by the portions between pillars (posts) 221 and vertical portions (posts) 227 during the etching.

The fins 233 in region (a) have a width l2, measured at the upper surface 101A of substrate 101, substantially equal to the width l2 of vertical portions (posts) 227 and a pitch p2 substantially equal to the pitch p2 between vertical portions (posts) 227. Similarly, the fins 234 in region (b) have a width l3, measured at the upper surface 101A of substrate 101, substantially equal to the width l3 of the portions between pillars (posts) 221 and a pitch p1 substantially equal to the pitch p1 between the portions between pillars (posts) 221. Thus, as explained hereabove, the fins 233 (thin fins) in region (a) are thinner and tighter than the fins 234 (wide fins) in region (b). For example, width l3 is greater than or equal to twice width l2. The thin fins 233 form the fins of FinFET transistors 10. The wide fins 234 may form fins for one or a plurality of transistors, such as MOSFET transistors, for example, HV transistors.

An advantage of forming a fin MOSFET transistor is that it provides a greater transistor width than a planar or mesa transistor. Indeed, since the transistor gate surrounds the fin, the gate comprises vertical portions around the fin which take part in conduction. Now, a greater transistor width for a same surface area in top view gives this transistor a better performance, for example 30% for a transistor width that increases from 80 nm in planar mode to 110 nm in fin mode.

As an example, trenches 231, 232 do not have, in cross-section view, a rectangular shape having its bottom orthogonal to the side surfaces. Trenches 231, 232 have, for example, in cross-section view a trapezoidal shape in which the width of trenches 231, 232 at the upper surface 101A of substrate 101 is greater than the width of trenches 231, 232 at the bottom of these trenches.

As an example, thin fins 233 have a width l2, taken at the upper surface 101A of substrate 101, smaller than 15 nm, for example smaller than or equal to 10 nm.

As an example, wide fins 234 have a width l3, taken at the upper surface 101A of substrate 101, greater than or equal to 20 nm, for example equal to approximately 30 nm.

Layers 202 and 203 are then removed.

FIG. 10 illustrates, in a partial cross-section view, a structure obtained at the end of a step of deposition of another layer of oxide 240, for example SiO₂, on the structure illustrated in FIG. 9. More specifically, during this step, oxide layer 240 is deposited in trenches 231 and 232, and on fins 233 and 234, that is, covers the upper surface 101A of substrate 101.

FIG. 11 illustrates, in a partial and simplified cross-section view, a structure obtained at the end of a step of removal of oxide layer 240 from an upper portion of the structure illustrated in FIG. 10.

More particularly, in a first step, oxide layer 240 is removed from the upper surface 101A of substrate 101. This removal is for example carried out by chemical mechanical polishing (CMP). The removal of oxide layer 240 is for example stopped when the upper surface 101A of substrate 101 is exposed.

In a second step, oxide layer 240 is removed from an upper portion of trenches 231, 232, so as to only keep an oxide portion 241, 242 of oxide layer 240 in a lower portion of trenches 231, 232. This removal is for example carried out down to a depth in the range from 10 nm to 100 nm, for example in the order of 50 nm. After this step, the thin 233 and wide 234 fins on which the various transistors will be manufactured are formed.

FIG. 12 shows, in a partial and simplified cross-section, a structure obtained at the end:

of the forming of an isolating trench 250 (STI) in substrate 101 between the two regions (a) and (b); then

of the forming of an etch mask 206 (PR2) covering region (a), but leaving region (b) exposed: more particularly, etch mask 206 is deposited in trenches 231 on oxide portions 241, on fins 233, and may be partially deposited on isolating trench 250; then

of a step of implantation 207 of a well in region (b) of substrate 101 not covered by etch mask 206.

Etch mask 206 is then removed, as shown in the top view of FIG. 13. It should be noted that, for simplification, the oxide portions 241, 242 in trenches 231, 232 have not been shown in FIG. 13. Thus, FIG. 13 shows thin fins 233 in region (a) and wide fins 234 in region (b) and an isolating trench 250 between regions (a) and (b).

As indicated hereabove, this first phase of the manufacturing method, illustrated in FIGS. 2 to 13, is then followed by a second phase, which may be similar to, or adapted from, the steps illustrated in FIGS. 20 to 30 described hereafter.

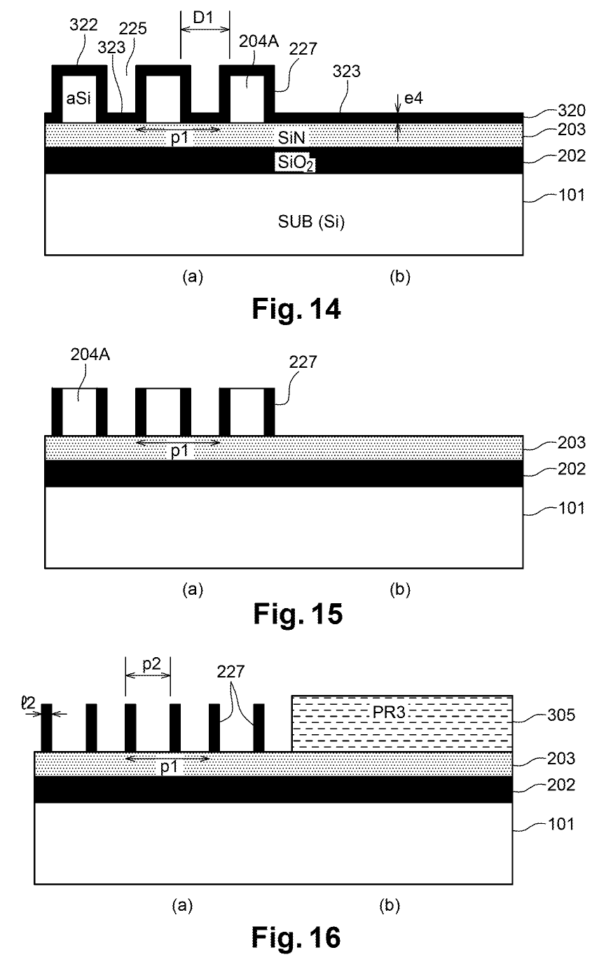

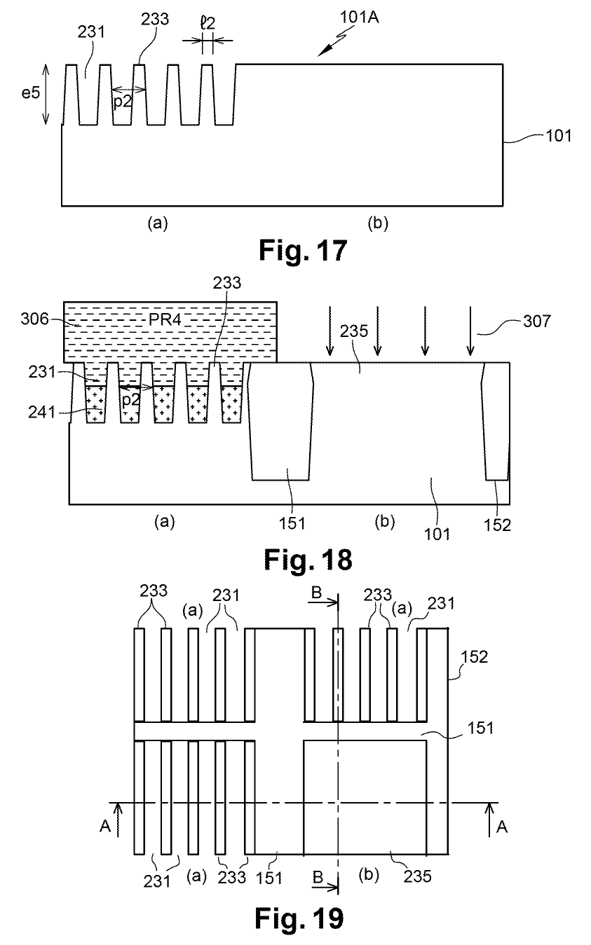

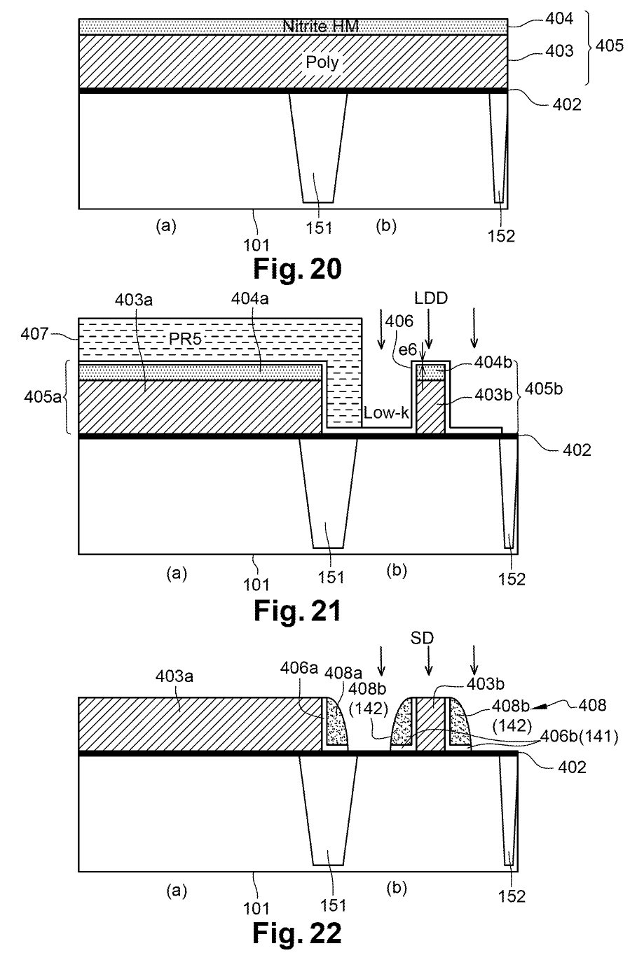

FIG. 14, FIG. 15, FIG. 16, FIG. 17, FIG. 18, FIG. 19, FIG. 20, FIG. 21, FIG. 22, FIG. 23, FIG. 24, FIG. 25A, FIG. 25B, FIG. 26, FIG. 27, FIG. 28, FIG. 29, and FIG. 30 are cross-section and top views illustrating steps of a second example of a method of manufacturing an electronic device according to an embodiment, corresponding to the electronic device 100 of FIG. 1.

FIGS. 14 to 19 illustrate a second example of the first phase of the manufacturing method, which is then followed by a second phase, the steps of which are illustrated in FIGS. 20 to 30.

The cross-section views of FIGS. 14 to 18 are obtained along cross-section plane AA, shown in mixed lines in FIG. 19, which is a top view of FIG. 18, after the removal of an etch mask.

The cross-section views of FIGS. 20 to 30 are obtained along the cross-section plane BB shown in mixed lines in FIG. 19. Cross-section plane BB is in particular obtained along a thin fin 233 of semiconductor substrate 101 and corresponds to the channel length direction of FinFETs (“Fin Field-Effect Transistors”) formed inside and on top of this fin 233. Cross-section plane BB is also obtained in the channel length direction of a MOSFET (Metal-Oxide-Semiconductor Field-Effect Transistor) formed inside and on top of semiconductor substrate 101 (inside and on top of an mesa 235). The cross-section views of FIGS. 20 to 30 could be obtained along the cross-section plane B′B′ shown in mixed lines in FIG. 13, which would then be along a thin fin 233 and along a wide fin 234 of semiconductor substrate 101.

The second example of the first phase shown in FIGS. 14 to 19 differs from the first example shown in FIGS. 2 to 13 in that it does not comprise the forming of wide fins in region (b). Thus, MOSFET transistor will be formed in region (b) on a planar portion of semiconductor substrate 101, which planar portion may be a mesa, that is, a planar portion surrounded by isolating trenches. The term “mesa” designates a form of an island.

FIG. 14 illustrates, in a partial and simplified cross-section view, an initial structure similar to the structure illustrated in FIG. 6, but without pillars 204B and portions 221, 222, 228 in region (b). Thus, the initial structure comprises semiconductor substrate 101 (SUB(Si)), layer 202 of oxide, for example a silicon oxide (SiO₂), on substrate 101, protective layer 203 made of dielectric material, for example of silicon nitride (SiN), on oxide layer 202, and pillars 204A made of amorphous silicon (aSi) in region (a). A layer 320 of oxide, for example of SiO₂, is deposited on pillars 204A and layer 203. Oxide layer 320 is similar to the oxide layer 220 described in relation with FIG. 6, and in particular it has a similar thickness e4, such that it does not fill the spaces between two adjacent pillars 204A in region (a). Preferably, thickness e4 is smaller than half the distance D1 between two pillars 204A.

Oxide layer 320 comprises:

substantially horizontal portions 322 on pillars 204A;

substantially horizontal portions 323 on layer 203 in region (b), between the two regions (a) and (b), and between pillars 204A in region (a); and

substantially vertical portions (posts) 227 on the sides of pillars 204A, similar to the vertical portions (posts) 227 described in relation with FIG. 6.

In region (a), oxide layer 320 follows the crenellated shape of the plurality of pillars 204A, forming U-shaped portions 225 between two adjacent pillars 204A, similar to the U-shaped portions 225 described in relation with FIG. 6.

FIG. 15 shows, in a partial and simplified cross-section view, a structure obtained at the end of a step of etching, preferably a dry etching, of oxide layer 320 so as to remove horizontal portions 322 and 323, while leaving vertical portions (posts) 227 in region (a). The etching of FIG. 15 is preferably carried out across a thickness substantially equal to the thickness e4 of oxide layer 220, so as to be able to expose pillars 204A.

FIG. 16 illustrates, in a partial and simplified cross-section view, a structure obtained at the end of a step of removal, by anisotropic wet etching, of pillars 204A, leaving only vertical portions (posts) 227 on layer 203. Vertical portions (posts) 227 are generally elongated in the direction perpendicular to FIG. 16, in the form of beams.

Similarly to the vertical portions (posts) 227 described in relation with FIG. 8, the vertical portions (posts) 227 of FIG. 16 have a width l2 substantially equal to the thickness e4 of oxide layer 320, or even less due to the etching of FIG. 15. Thus, the vertical portions (posts) 227 have a width l2 smaller than half the distance D1 between two pillars 204A. Further, since each mandrel 204A has been replaced by two vertical portions (posts) 227, vertical portions (posts) 227 have a pitch p2 much smaller than the pitch p1 between pillars 204A, for example approximately half pitch p1. For example, for a pitch p1 substantially equal to 80 nm, a pitch p2 substantially equal to 40 nm can be obtained.

The values of distance D1, of the width d1 of pillars 204A, and of the thickness e4 of oxide layer 320 may advantageously be defined so that the vertical portions (posts) 227 have the same pitch p2.

Then, after this removal step, an etch mask 305 (PR3) is formed over region (b).

FIG. 17 shows, in a partial and simplified cross-sectional view, a structure obtained at the end of the etching of semiconductor substrate 101, through layers 203 and 202, which are also etched. The etching of FIG. 17 is similar to that described in relation with FIG. 9, except that it is carried out in region (a), but semiconductor substrate 101 is not etched in region (b), protected by etch mask 305.

This etching is carried out through vertical portions (posts) 227, also forming an etch mask in region (a).

This etch step forms, in substrate 101, trenches 231 in region (a) similar to the trenches 231 shown in FIG. 9. Trenches 231 extend from the upper surface 101A of substrate 101, down to a depth e5 smaller than the thickness of substrate 101. The forming of trenches 231 enables to define fins 233 between trenches 231. Fins 233 correspond to the unetched portions of semiconductor substrate 101 in region (a), protected by the vertical portions (posts) 227. Trenches 231 and fins 233 are formed only in region (a), region (b) remaining substantially planar.

Fins 233 have a width, measured at the upper surface 101A of substrate 101, substantially equal to the width l2 of vertical portions (posts) 227 and a pitch p2 substantially equal to the pitch between vertical portions (posts) 227.

Fins 233 form the fins of FinFET transistors 10.

As an example, fins 233 have a width, taken at the upper surface 101A of substrate 101, smaller than 15 nm, for example smaller than or equal to 10 nm.

Layers 202 and 203 are then removed.

The steps of deposition of another oxide layer in trenches 231, and on fins 233, then of removal of this oxide layer from the top of fins 233 and over an upper portion of trenches 231 may then be carried out, so as to only keep a portion of oxide 241 in a lower portion of trenches 231, similarly to what is described in relation with FIGS. 10 and 11, but only in region (a). In this case, a new mask is thus provided on the upper surface 101A of substrate 101 in region (b). This may be done before, or after, the forming of isolating trenches 151 and 152 described in the following.

FIG. 18 shows, in a partial and simplified cross-section view, a structure obtained at the end of the forming of an isolating trench 151 (STI) in substrate 101 between the two regions (a) and (b), and of an isolating trench 152 (STI) on the other side of region (b) with respect to isolating trench 151. Trenches 151 and 152 form a mesa 235 of semiconductor substrate 101 in region (b).

Then, similarly to what is described in relation with FIG. 12, an etch mask 306 (PR4) is formed, covering region (a), but leaving region (b) exposed: more particularly, etch mask 306 is deposited in trenches 231 on oxide portions 241, on fins 233 and may be partially deposited on isolating trench 151; then a step of implantation 307 of a well in region (b) of substrate 101 not covered by etch mask 306 is carried out.

Etch mask 306 is then removed, as illustrated in the top view of FIG. 19. It should be noted that, for simplification, FIG. 19 does not show the oxide portions 241 in trenches 231.

As previously indicated, a second phase of the manufacturing method is described in the following, in relation with FIGS. 20 to 30, according to the cross-sections BB shown in FIG. 19. This second phase particularly enables to form sacrificial gates of the FinFET and MOSFET transistors, to form semiconductor regions 11, corresponding to the source and drain regions of FinFET transistors 10, and semiconductor regions 12, corresponding to the source and drain regions of MOSFET transistor 20, and then to complete the gate structures 110 and 120 of the FinFET and MOSFET transistors (so-called “gate replacement” steps).

The described sacrificial gates comprise a sacrificial material, generally a semiconductor material, which is polysilicon in the described examples. The described sacrificial gates may also comprise, on the sacrificial material, a dielectric layer, for example made of silicon nitride, although this example is not limiting.

The steps described in the following (second phase) are based on a FinFET transistor manufacturing technology and are adapted to forming, in co-integration with FinFET transistors, MOSFET transistors that may be HV transistors. It should be noted that the above-described steps (first phase) are also based on a FinFET transistor manufacturing technology.

FIG. 20 shows, in a partial and simplified cross-section view, a structure obtained at the end of the deposition, on the structure of FIG. 19:

of a protective or etch stop layer 402 on the upper surface 101A of substrate 101;

- of a polycrystalline silicon or polysilicon layer 403 (Poly) on layer 402;

of a protective layer 404, or hard mask (Nitride HM), on polysilicon layer 403.

Etch stop layer 402 is advantageously made of an oxide, for example of silicon oxide, for example SiO₂. This etch stop layer 402 is more particularly made of a material enabling to perform an etching selective over polysilicon. This selective etch step is described in the following description in relation with FIGS. 25A and 25B.

Protective layer 404 may be made of a nitride, for example, a silicon nitride, or even an oxide, for example, a silicon oxide.

FIG. 21 shows, in a partial and simplified cross-section view, a structure obtained at the end of the steps described in the following.

An etching of the stack 405 of layers 403 and 404 in region (b) is performed.

Before performing this etching, an etch mask (not shown) is deposited on layer 404. The etch mask is configured to mask the entire region (a), for example up to above a portion of isolating trench 151, as well as a substantially central portion of region (b), and leave the other portions of region (b) exposed.

After this etching through this etch mask, the stack 405 of etched layers 403 and 404 forms a stack 405a of unetched portions 403a and 404a in region (a), and a stack 405b of unetched portions 403b and 404b in region (b), this stack 405b enabling to draw the location of the future sacrificial gate structure of MOSFET transistor 20.

A layer 406 of a material of low permittivity, or low dielectric constant (low-k), is deposited on the upper surfaces and against the flanks of stacks 405a and 405b, as well as on the exposed portions of layer 402. In other words, layer 406 follows the shapes of the structure obtained at the end of the etching of stack 405. The low-k material is, for example, SiOCN or SiBCN.

For example, layer 406 has a thickness e6 in the range from 3 to 10 nm, for example equal to approximately 5 nm.

Then, a mask 407 (PR5) is formed on stack 405a, and extends over the flank of stack 405a all the way to a portion of layer 406 between stacks 405a and 405b. This mask 407 enables to mask region (a), and possibly a portion of region (b), during a step of ion implantation of substrate 101 in region (b), from upper surface 101A and on either side of stack 405b, so as to form LDD (Lightly Doped Drain) semiconductor regions.

Low-k layer 406 enables to have in region (b) for the MOSFET transistor the same framing (low-k spacers 406b) around polysilicon 403b as what will be, later in the method, around polysilicon 403c in region (a) (low-k spacers 421 described hereafter) for the FinFET transistors (see FIGS. 25A and 25B and the corresponding description). Thus, when the sacrificial gates are removed, that is, polysilicon 403c and 403b respectively in region (a) and region (b) (see FIG. 28 and the corresponding description), the etching may be selective over the same low-k material on the side of the FinFET transistors and of the MOSFET transistor.

Mask 407 is then removed.

FIG. 22 shows, in a partial and simplified cross-section view, a structure obtained at the end of the steps described in the following.

After the removal of mask 407, a nitride layer 408, for example made of silicon nitride, is deposited on stacks 405a and 405b and on layer 406. Then, a nitride etching is performed, which includes layer 408, low-k layer 406, the portions 404a and 404b of nitride layer 404, stopping on the portions 403a and 403b of polysilicon layer 403 and on layer 402. This results in the forming of spacers on the flanks of polysilicon portions 403a and 403b.

In region (b), the formed spacers comprise:

L-shaped portions 406b of layer 406: L-shaped portions 406b each comprise a vertical portion against a flank of polysilicon portion 403b, the vertical portion extending in a horizontal portion on layer 402; and

D-shaped spacers 408b in contact with L-shaped spacers 406b.

Portions 406b form, for example, the spacers 141 shown in FIG. 1. Spacers 408b correspond, for example, to the spacers 142 shown in FIG. 1.

In region (a), the formed spacers comprise:

another L-shaped portion 406a of layer 406: this other portion 406a comprises a vertical portion against a flank of polysilicon portion 403a (only one flank can be seen in FIG. 22, but generally there are two), the vertical portion extending in a horizontal portion on layer 402; and

a D-shaped spacer 408a in contact with L-shaped spacer 406a in region (a).

Once spacers 406b and 408b have been formed, a step of implantation of substrate 101 may be carried out in region (b), from upper surface 101A and on either side of polysilicon portion 403b flanked by spacers 406b and 408b, so as to form the drain and source regions (SD) of MOSFET transistor 20.

This implantation step is preferably carried out after the forming of a mask on region (a). Although only one MOSFET transistor has been shown in region (b), there may be a plurality of MOSFET transistors, for example of NMOS type and of PMOS type. In this case, one or a plurality of masks may also be provided on region (b) to mask future PMOS transistors during the N-type implantation and similarly to mask future NMOS transistors during the P-type implantation.

This implantation step is however optional at this stage of the method and may be carried out in a subsequent step, as described later in the disclosure in relation with FIGS. 25A and 25B.

FIG. 23 shows, in a partial and simplified cross-section view, a structure obtained at the end of a step of deposition of a protective layer 410, or hard mask (SiN HM), made of a dielectric material, such as a nitride, for example, a silicon nitride, on the structure shown in FIG. 22.

Layer 410 has a thickness e7, measured from the upper surface of polysilicon portion 403a, for example greater than 30 nm.

FIG. 24 illustrates, by a partial and simplified cross-section view, a structure obtained at the end of a step of etching of layer 410 through an etch mask (mask not shown) configured to form:

in region (a): a plurality of portions 411 of layer 410 on polysilicon portion 403a and a portion 412 of layer 410 forming another spacer on spacer 408a; and

in region (b): a portion 413 of layer 410 on polysilicon portion 403b and portions 414 of layer 410 forming other spacers on spacers 408b.

Portions 411 are arranged in a row, that is, arranged side by side along a same direction, and appear in FIG. 24 in the form of posts, but they generally extend in the direction perpendicular to FIG. 24, forming, for example, beams.

Spacers 414 correspond, for example, to the spacers 143 shown in FIG. 1.

Portion 413 has a length L5 which is greater than the length L4 of polysilicon portion 403b. Preferably, portion 413 extends on either side of polysilicon portion 403b, to extend above spacers 406b, or even above spacers 408b.

For example, portion 413 enables to protect polysilicon portion 403b during the etching operations described in the following description.

FIGS. 25A and 25B show, in two partial and simplified cross-section views, structures illustrating two variants for forming the semiconductor regions 11 (sources and drains) of FinFET transistors 10.

Before forming these semiconductor regions 11, in a way common to the two variants, the polysilicon portion 403a in region (a) is etched, the polysilicon portion 403b in region (b) being protected from this etching in particular by portion 413 of 410 layer and by spacers 406b, 408b, 414. Further, the posts 411 on polysilicon portion 403a form in region (a) patterns of an etch mask, while protecting from etching the polysilicon portions located under these posts 411. The etching thus enables to form polysilicon posts 403c aligned under posts 411.

In region (a), sacrificial gates 430 each comprise a stack of a post 411 of dielectric material on a polysilicon post 403c.

In region (b), sacrificial gate 440 comprises polysilicon portion 403b covered on its flanks by spacers 406b, 408b, 414 made of dielectric material and on its upper surface by portion 413 made of dielectric material.

Sacrificial gate 440 has a length L4, and sacrificial gates 430 have a length L3 smaller than length L4. The length L3 of sacrificial gates 430 substantially corresponds to the length L1 of the gate structures 110 of FIG. 1. The length L4 of sacrificial gate 440 substantially corresponds to the length L2 of the gate structure 120 of FIG. 1.

The polysilicon etching stops on oxide layer 402 forming the etch stop layer. Another etching then enables to remove all the portions of oxide layer 402 exposed in regions (a) and (b). There remain portions 402a of oxide layer 402 under sacrificial gates 430, and a portion 402b of the oxide layer under sacrificial gate 440 and spacers 406b, 408b, 414. The portion 402b of oxide layer 402 for example forms all or part of the insulating portion 126 shown in FIG. 1.

The spacers 406a, 408a, and 412 in region (a) are generally kept, although this is not shown in FIGS. 25A, 25B and the following: these spacers may be used as a transition between the FinFET transistors and the MOSFET transistor(s).

A layer 420 of a low-k dielectric material is then deposited on sacrificial gates 430, 440 and on the upper surface 101A of substrate 101. Preferably, the low-k material of layer 420 is the same as the low-k material of layer 406.

This layer 420 is then etched in region (a) so as to remove the portions of layer 420 located on substrate 101 and above sacrificial gates 430, and to only keep in region (a) portions 421 on the flanks of sacrificial gates 430.

The portions 421 in region (a) form spacers which will in particular enable to keep the shape of sacrificial gates 430 during the gate replacement steps described hereafter in relation with FIGS. 28 to 30. Portions 421 form, for example, the spacers 131 shown in FIG. 1, and have a thickness e8 for example in the range from 3 to 10 nm, or smaller than 15 nm.

An etch mask (not shown) is formed to mask all or part of region (b), while leaving region (a) exposed. This etch mask is configured differently according to the variants of FIGS. 25A and 25B.

After deposition and etching of layer 420, semiconductor regions 11 are formed at least in region (a), in substrate 101, on either side of the sacrificial gates 430 coated with spacers 421.

Preferably, semiconductor regions 11 are formed by epitaxy in substrate 101. In particular, cavities 409a are formed in region (a) of substrate 101 from upper surface 101, on either side of sacrificial gates 430 coated with spacers 421, and these cavities 409a are then filled by in-situ doped epitaxy of type P (for example SiGeB) to form PMOS-type FinFET transistors, and/or of type N (for example, SiP) to form NMOS-type FinFET transistors.

In the variant of FIG. 25A, the etch mask covers the entire region (b), or even further extends over isolating trench 151, so that layer 420 is entirely kept in region (b). In particular, horizontal portions 423 of layer 420 are kept on the upper surface 101A of substrate 101 on either side of sacrificial gate 440. Further, portions 422 of layer 420 are kept in region (b) on spacers 414, these portions 422 for example forming other spacers, and portions 424 covering portion 413.

Spacers 422 correspond, for example, to the spacers 144 shown in FIG. 1.

In this variant, layer 420 protects the entire region (b) from the etching and epitaxy operations performed in region (a). Thus, the semiconductor regions 12 of MOSFET transistor 20 are not formed at the same time as the semiconductor regions 11 of FinFET transistors 10.

The variant of FIG. 25A enables to form semiconductor regions 12 which are not necessarily identical to semiconductor regions 11, and which, for example, are closer to the drain and source regions conventionally formed for MOSFET transistors than those formed for FinFET transistors. Semiconductor regions 12 may be formed by ion implantation in an earlier step, for example during the step illustrated in relation with FIG. 24 or with FIG. 22, or even after the forming of semiconductor regions 11. As a variant, semiconductor regions 12 may be formed by epitaxy, similarly to semiconductor regions 11, but in an earlier or later step.

In the variant of FIG. 25B, the etch mask does not cover region (b).

In this variant, the semiconductor regions 12 of MOSFET transistor 20 are formed at the same time as semiconductor regions 11. Preferably, semiconductor regions 12 are formed by epitaxy in substrate 101. In particular, cavities 409b are formed in substrate 101 in region (b) from upper surface 101A, on either side of sacrificial gates 440 coated with spacers 406b, 408b, 414 (or even 422), after which these cavities 409b are filled by epitaxy and implantation of P-type (for example SiGeB) and/or N-type (for example SiP) dopant atoms to form a PMOS-type MOSFET transistor. These operations of forming and filling of cavities 409b may advantageously be carried out at the same time as those for cavities 409a.

The variant of FIG. 25B enables to decrease the number of masks, and thus manufacturing costs, since it is not necessary to mask region (a) during the forming of semiconductor regions 12 in region (b) and to mask region (b) during the forming of semiconductor regions 11 in region (a).

As shown in FIG. 25B, there may remain after etching a thin thickness of layer 420 on sacrificial gate 440: for example, a thin thickness of portions 422 of layer 420 on spacers 414, which may form further spacers, and a thin thickness of portions 424 covering the flanks of portion 413. As a variant, the etching may remove the entire layer 420 in region (b) so that layer 420 does not cover sacrificial gate 440 at all.

Spacers 406b, 408b, 414, and optionally 422, form a multi-layer dielectric spacer structure similar to the spacer structure 140 shown in FIG. 1.

For example, spacers 406b (141) have a thickness in the range from 3 to 10 nm, or smaller than 15 nm. For example, spacers 408b (142) have a thickness in the range from 15 to 40 nm. For example, spacers 414 (143) have a thickness in the range from 10 to 20 nm. For example, spacers 422 (144) have a thickness in the range from 3 to 10 nm. For example, the spacer structure (140) has a total thickness e9, taken at the level of the upper surface 101A of substrate 101, in the range from 30 to 60 nm, or greater than 30 nm.

The spacer structure thus formed has a significant thickness due to the stacking of these spacers. Advantage can be taken of this large thickness to form the drain and source regions of MOSFET transistor 20, since this enables to increase the channel length between the drain and source regions. This enables in particular to increase the operating voltage of MOSFET transistor 20, in particular so that it is adapted to operating at the high voltage. For example, the channel length of MOSFET transistor 20 is greater than or equal to 200 nm.

In the rest of the disclosure, it is started from FIG. 25B, but those skilled in the art may easily adapt the described steps in the following by starting from FIG. 25A.

FIG. 26 shows, in a partial and simplified cross-section view, a structure obtained at the end of the steps of:

deposition of an etch stop layer 451, for example a nitride layer, on the structure illustrated in FIG. 25B, that is, on substrate 101 and on sacrificial gates 430 and 440 coated with their spacers;

deposition of a layer 452 of oxide, for example, of SiO₂, on layer 451.

For example, an upper portion of layer 452 which extends beyond the upper surface of sacrificial gates 430 and 440 is removed, for example by a chemical mechanical polishing (CMP).

Layer 452 fills the spaces between the portions of upper surface 101A covered by layer 451 and the flanks of sacrificial gates 430 and 440 covered by spacers 421 and 406b, 408b, 414, 422 and by layer 451. Thus, layer 452 comprises a plurality of portions in these spaces.

Further, an upper portion of sacrificial gates 430 and 440, and of the spacers 421 and 406b, 408b, 414, 422 of these sacrificial gates, and of layer 451 (upper portions of layer 451 which are on the flanks of the sacrificial gates) is removed so as to access at least portions 411 and 413 in the sacrificial gates.

Thus, sacrificial gates 431 and 441 of decreased thickness, or height, are obtained.

These removals are preferably performed so that sacrificial gates 431 and 441, spacers 421 and 406b, 408b, 414, 422, layer 451, and layer 452 are flush with the same upper level.

FIG. 27 shows, in a partial and simplified cross-section view, a structure obtained at the end of the steps of:

removal of another upper portion of layer 452 by etching, preferably over a height h2 such that the etched layer 452 is substantially flush with, or even below, the upper surface of polysilicon portions 403c and 403b: this removal is carried out without etching sacrificial gates 431 and 441, spacers 421 and 406b, 408b, 414, 422, and layer 451; then

deposition of a protective nitride layer 453, for example SiN, on etched layer 452 and sacrificial gates 431 and 441;

planarization, for example by CMP, of nitride layer 453, so as to remove the nitride on sacrificial gates 431, 441: a thickness of layer 453 substantially equal to the etching height h2 of layer 452 is obtained.

FIG. 28 shows, in a partial and simplified cross-section view, a structure obtained at the end of the steps of:

removal down to the level of polysilicon 403c, 403b, for example by CMP selective over polysilicon, of portions 411 and 413 in sacrificial gates 431 and 441, of layer 453, and of a partial height of spacers 421, 406b, 408b, 414, 422 and of layer 451 (the removal of these layers and spacers corresponds substantially to a removal over height h3 of portions 431 and 441): for example, height h2 is greater than height h3, so that there may remain a height (h2 minus h3) of layer 453 flush with sacrificial gates 431 and 441, spacers 421, 406b, 408b, 414, 422 and layer 451; then

removal by etching of polysilicon portions 403c and 403b in sacrificial gates 431 and 441.

Layer 451 having its height decreased for example forms the layer 103 shown in FIG. 1.

Layer 452 having its thickness decreased forms, for example, the layer 104 shown in FIG. 1.

Sacrificial gates 432 and 442 having a thickness, or height, decreased again are obtained.

FIG. 29 shows, in a partial and simplified cross-section view, a structure obtained at the end of the following steps.

A layer 454 of oxide, for example SiO₂, is deposited on the structure shown in FIG. 28. Layer 454 follows the shape of the structure of FIG. 28, and in particular is deposited inside, on the bottom and the side walls, of sacrificial gates 432 and 442.

Then, an etch mask 455 (PR6) is formed over oxide layer 454 in region (b). Etch mask 455 leaves exposed the portion of oxide layer 454 in region (a), which is then removed.

Etch mask 455 is then removed.

FIG. 30 shows, in a partial and simplified cross-sectional view, a structure obtained at the end of the steps of filling of sacrificial gates 432 and 442. The filling materials are, for example, those described in the description of FIG. 1, and are not described again here.

The structure of FIG. 30 corresponds to the electronic device 100 of FIG. 1, which will not be described again here.

The portion of oxide layer 454 located on layer 453 in region (b), outside sacrificial gate 442, is removed after filling of the gates with a metallic material, which is generally followed by a CMP planarization. Layer 453 of decreased thickness has also been removed at the same stage of the method.

There remains an unetched portion of oxide layer 454 located on the bottom and the side walls inside sacrificial gate 442, this unetched portion of oxide layer 454 for example forming the gate insulator layer 121 shown in FIG. 1.

Those skilled in the art will be capable of adapting the second phase of the manufacturing method by starting from the structure of FIGS. 12 and 13, instead of from FIGS. 18 and 19. In other words, instead of forming the MOSFET transistor on a mesa (or as a complement as described hereafter), the MOSFET transistor may be formed along a wide fin 234.

An advantage of forming the MOSFET transistor on a mesa is to limit the risks of hot carriers, while an advantage of forming the MOSFET transistor on a wide fin is to increase the performance, all the more so if the variant described in FIG. 25B is selected to form the drain and source regions of the MOSFET transistor.

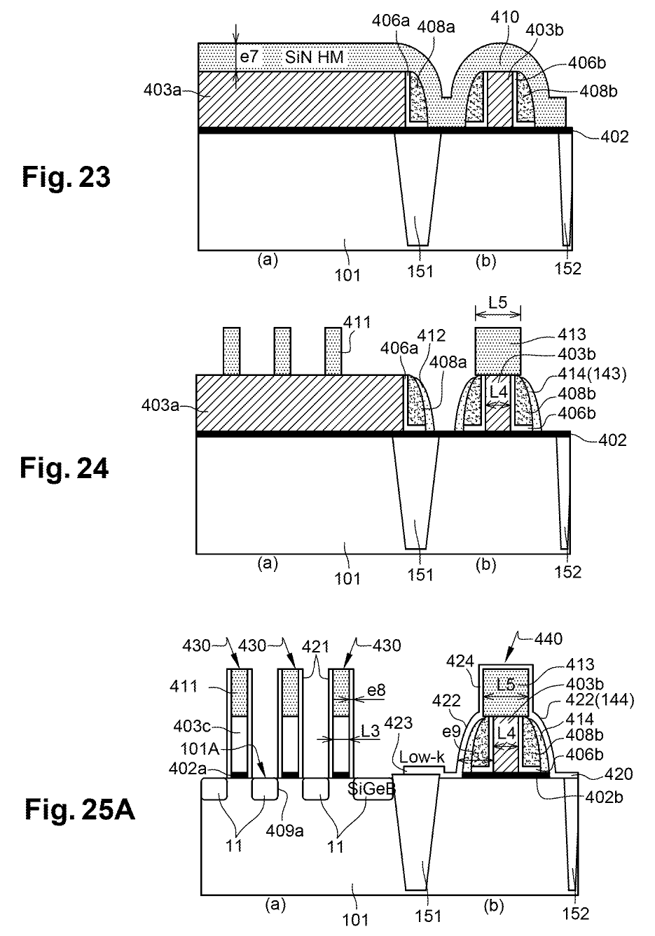

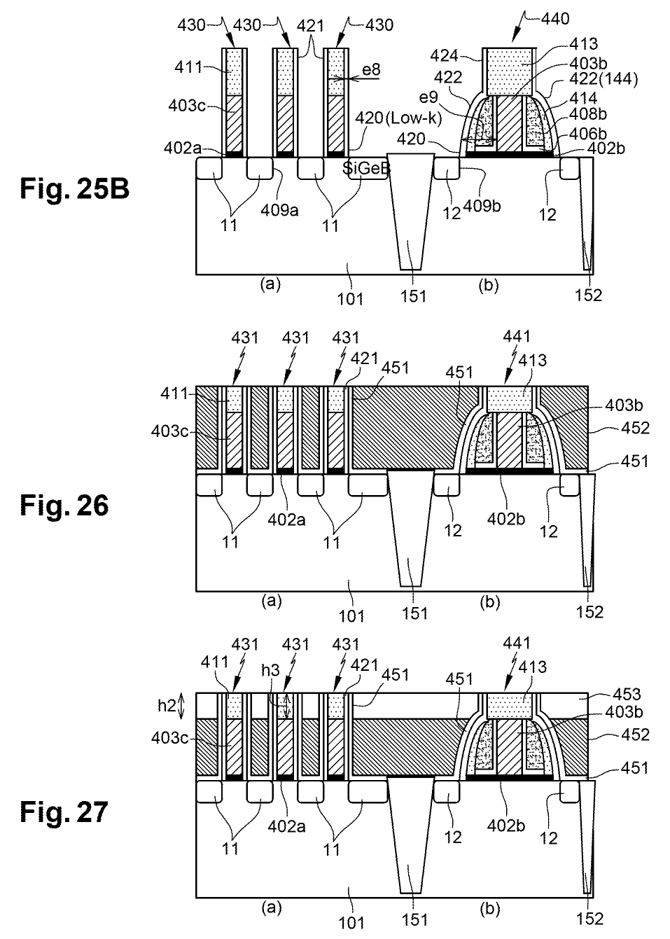

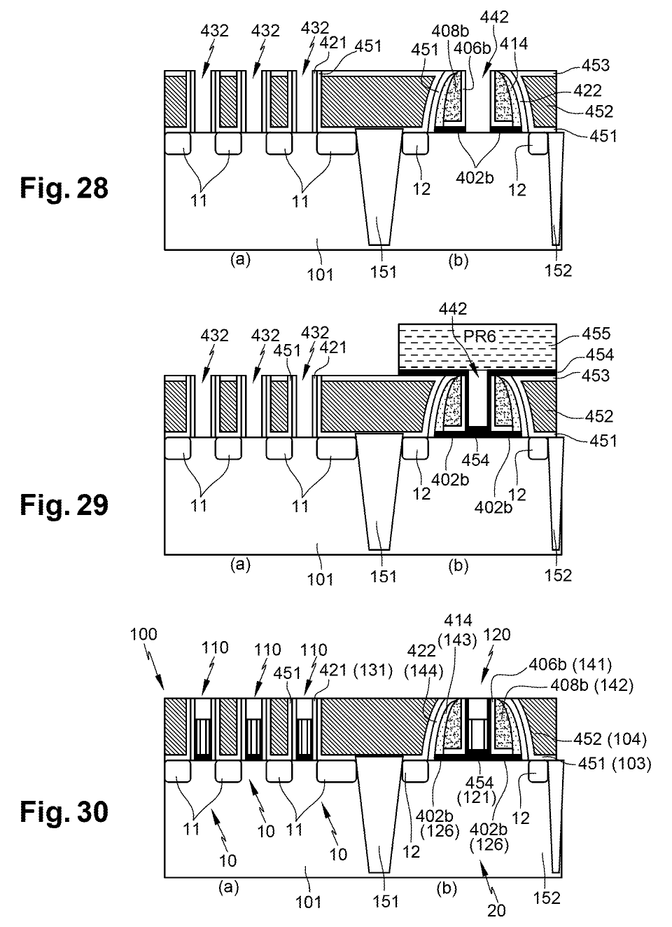

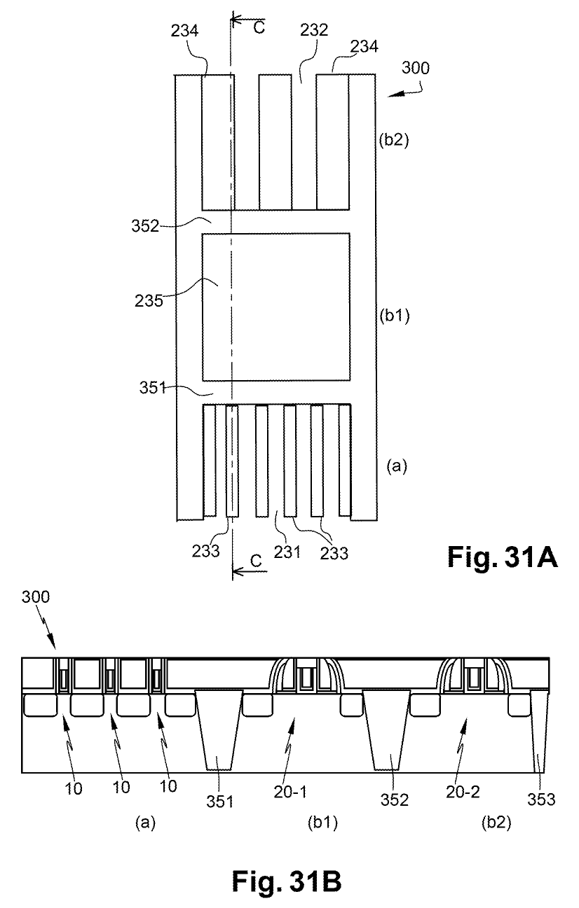

FIG. 31A and FIG. 31B are partial and simplified cross-section views of another example of an electronic device 300 according to an embodiment. FIG. 31A is a cross-section view taken across the isolating trenches and semiconductor substrate 101. FIG. 31B is a cross-section view along the cross-section plane CC shown in FIG. 31A.

The electronic device 300 of FIGS. 31A and 31B differs from the electronic device 100 of FIGS. 1 and 30 in that it comprises three regions (a), (b-1), (b-2): a thin fin region (a), a mesa region (b-1), and a wide fin region (b-2).

The thin fins 233 in region (a) are similar to the fins 233 described in relation with FIGS. 9 to 13, or FIGS. 18 and 19. The mesa 235 in region (b-1) is similar to the mesa 235 described in relation with FIGS. 18 and 19. The wide fins 234 in region (b-2) are similar to the fins 234 described in relation with FIGS. 9 to 13.

FIG. 31B shows FinFET transistors 10 along a thin fin 233 in region (a), a MOSFET transistor 20-1 on top and inside of the mesa 235 in region (b1), a MOSFET transistor 20-2 along a wide fin 234 in region (b2).

Region (a) is insulated from region (b-1) by an isolating trench 351, and region (b-2) is insulated from region (b-1) by another isolating trench 352. Region (b-2) is also insulated by a further isolating trench 353 on the side opposite to isolating trench 352.

Transistors 10, 20-1, and 20-2, for example, are formed in a same manufacturing method, which may be similar to that described in relation with FIGS. 20 to 30, by adapting the described method.

It will be understood that, in practice, instead of having region (b-1) between regions (a) and (b-2), one could have region (b-2) between regions (a) and (b-1), or region (a) between regions (b-1) and (b-2). There could also be other regions, and/or other orientations or configurations of regions, and more generally any other configuration of regions in which at least one region comprises one or a plurality of FinFET transistors and at least another region comprises one or a plurality of MOSFET transistors, for example one or a plurality of HV MOSFET transistors. The MOSFET transistors and/or the FinFET transistors may comprise at least one PMOS transistor and one NMOS transistor.

An advantage of the embodiments is that they enable to integrate, within one and the same electronic device, FinFET transistors and high-voltage MOSFET transistors, on a wide fin and/or on a mesa, while being compatible with standard FinFET transistor manufacturing methods. Indeed, embodiments enable in particular the forming of the spacers in a MOSFET transistor by means of steps present in the usual FinFET transistor manufacturing method.

Many applications are likely to benefit from the advantages provided by an electronic device according to an embodiment, which electronic device can thus be integrated into various types of devices. In particular, the above-described embodiments are adapted to any type of device providing analog and logic functions in a same electronic chip, for example a microcontroller.

As an example, the electronic device may be integrated in a device intended for the automotive industry, for example in the field of automotive electrification or in the field of advanced driver assistance systems.

As an example, the electronic device may be integrated in a device intended for industry.

As an example, the electronic device may be integrated in a device intended to be used in personal electronics.

As an example, the electronic device may be integrated in a device intended to be used in communications equipment, or in computers and peripherals.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

A method of manufacturing, inside and on top of a semiconductor substrate (101), an electronic device (100; 300) is summarized as including first fin field-effect transistors (10) in a first region (a), and at least one second field-effect transistor (20; 20b-1, 20b-2) with a metal-oxide-semiconductor structure (MOSFET) in at least one second region (b; b1, b2), the method including: the forming, in the first region, of first sacrificial gates (430) of a first length (L3) along a first fin (233) of the semiconductor substrate (101), said first fin having a first width (l2) at a first surface (101A) of the semiconductor substrate and being isolated by first trenches (231) in the semiconductor substrate, and, in each second region, of a second sacrificial gate (440) of a second length (L4) greater than the first length (L3) on the first surface (101A) of the semiconductor substrate, the first and second sacrificial gates being made of a sacrificial material; the forming of the first and second sacrificial gates including the forming of first spacers (421) of a first thickness (e8) on the flanks of the first sacrificial gates (430) and of second spacers (406b, 408b, 414, 422) of a second thickness (e9) greater than the first thickness (e8) on the flanks of the second sacrificial gate (440); the forming, in the semiconductor substrate, of first semiconductor regions (11) in the first region on either side of the first sacrificial gates (430) flanked by the first spacers, forming drain and source regions of the first transistors; the forming, in the semiconductor substrate, of second semiconductor regions (12) in each second region on either side of the second sacrificial gate (440) flanked by the second spacers, forming drain and source regions of the at least one second transistor; and the replacing of each first sacrificial gate (430) with a first gate structure (110) and of each second sacrificial gate (440) with a second gate structure (120).

The forming of the first and second sacrificial gates includes: the forming, on the semiconductor substrate (101), of a first portion (403a) of a first layer (403) made of the sacrificial material in the first region (a), and of a second portion (403b) of the first layer in each second region (b; b1, b2), said first portion extending over substantially the entire length of the first region, and said second portion extending over the second length (L4), shorter than the length of the second region, forming all or part of the second sacrificial gate (440); the forming, on the flanks of the first (403a) and second (403b) portions of the first layer (403), of a stack of layers made of dielectric material; the stack of layers made of dielectric material on the flanks of the second portion (403b) of the first layer (403) forming all or part of the second spacers (406b, 408b, 414, 422).

The forming of the stack of layers includes: the forming, on the flanks of the first portion (403a) of the first layer (403), respectively of the second portion (403b) of the first layer (403), and on the semiconductor substrate (101), of first L-shaped portions (406a), respectively second L-shaped portions (406b), of a second layer (406) made of dielectric material, preferably made of a low permittivity material; the forming, on the first L-shaped portions (406a), respectively second L-shaped portions (406b), of first D-shaped portions (408a), respectively second D-shaped portions (408b), of a third layer made of dielectric material, for example of a nitride, for example of a silicon nitride; the forming, on the first D-shaped portions (408a), respectively second D-shaped portions (408b), of first portions (412), respectively second portions (414), of a fourth layer (410) made of dielectric material, for example of a silicon nitride.

The forming of the first (412) and second (414) portions of the fourth layer (410) includes the deposition and then the etching of said fourth layer so as to form: in the first region: the first portions (412) and third portions (411) of said fourth layer on the first portion (403a) of the first layer (403), said third portions being arranged in a row and each extending over a length substantially equal to the first length (L3); and in each second region: the second portions (414) and a fourth portion (413) of said fourth layer on the second portion (403b) of the first layer (403).

A method includes the etching of the first portion (403a) of the first layer (403) so as to form third portions (403c) of said first layer arranged in a row and each extending over a length substantially equal to the first length (L3), forming all or part of the first sacrificial gates (430).

The etching of the first portion (403a) of the first layer (403) is performed through the third portions (411) of the fourth layer (410) forming the etch mask, the third portions (403c) of the first layer (403) extending between the semiconductor substrate (101) and the third portions (411) of the fourth layer (410).

The forming of the first and second spacers includes, after the forming of the third portions (403c) of the first layer (403), the forming of first portions (421) of a fifth layer (420) of a dielectric material, preferably of low permittivity, on the flanks of the first sacrificial gates (430), forming the first spacers, and of second portions (422) of said fifth layer on the flanks of each second sacrificial gate (440) covered by the stack of layers, the second spacers including said second portions of said fifth layer.

The forming of the second semiconductor regions (12) is performed at the same time as the forming of the first semiconductor regions (11).

The forming of the second semiconductor regions (12) is performed before or after the forming of the first semiconductor regions (11).

The fifth layer (420) includes a third portion (423) extending on either side of the second sacrificial gate (440) and of the second spacers in each second region, so as to mask the semiconductor substrate (101) in said second region during the forming of the first semiconductor regions (11).

An electronic device (100; 300) is summarized as including, inside and on top of a semiconductor substrate (101), first fin field-effect transistors (10) in a first region (a) and at least one second field-effect transistor (20; 20-1, 20-2) of metal-oxide-semiconductor structure (MOSFET) in at least one second region (b; b1, b2); the first transistors each including a first gate structure (110) of a first length (L1) along a first fin (233) of the semiconductor substrate (101), said first fin having a first width (l2) at a first surface (101A) of the semiconductor substrate and being isolated by first trenches (231) in the semiconductor substrate, each first gate structure (110) being flanked by a first spacer (131) having a first thickness (e8); each second transistor including a second gate structure (120) of a second length (L2) on the first surface (101A) of the semiconductor substrate, the second length being greater than the first length, each second gate structure being flanked by a second spacer (140) having a second thickness (e9) greater than the first thickness (e8).

A third transistor (20; 20-1) of the at least one second transistor is formed on top and inside of a mesa (235) flush with the first surface (101A) of the semiconductor substrate (101), in a third region (b; b-1) of the at least one second region.

A fourth transistor (20-2) of the at least one second transistor is formed along a second fin (234) of the semiconductor substrate (101), in a fourth region (b-2) of the at least one second region, the second fin (234) having a second width (l3) at the level of the first surface (101A) of the semiconductor substrate, and being isolated by second trenches (232) in the semiconductor substrate, the second width (l3) being greater than the first width (l2); for example: the second width is at least twice greater than the first width; and/or the first width is smaller than 15 nm, for example smaller than or equal to 10 nm; and/or the second width is greater than 20 nm, for example greater than or equal to 30 nm.

The method includes the forming of the first fin (233) in the first region (a) and of the second fin (234) in the fourth region (b-2), the forming of said first and second fins including: the forming, on the first surface (101A) of the semiconductor substrate (101), of first pillars (204A) in the first region (a) and of second pillars (204B) in the fourth region (b-2), the first and second pillars being arranged side by side in a row, and being made of a first material, for example an amorphous silicon, the first pillars being separated from one another by a first distance (D1), and the second pillars being separated from one another by a second distance (D1); the deposition, on the first and second pillars, of a sixth layer (210) made of a second material, for example a silicon oxide, selectively etchable over the first material, the sixth layer having a third thickness (e3) on the flanks of the first and second pillars; the removal of the sixth layer (210) in the first region (a), said sixth layer being kept on the flanks of the second pillars (204B) in the fourth region (b-2); the deposition, on the first and second pillars, of a seventh layer (220) made of the second material, the seventh layer having a fourth thickness (e4) defined to form, on the flanks of the first pillars (204A), first posts (227) separated from one another between the first pillars; the sixth and seventh layers forming, on the flanks of the second pillars (204B), second posts (228), the third and fourth thicknesses being defined so that the second posts (228) are joining between the second pillars (204B), the joining second posts forming third posts (221) coupling two adjacent second pillars; and the removal, for example by etching, of the first and second pillars made of the first material; the etching of the semiconductor substrate (101) from the first surface (101A) through the first, second, and third posts made of the second material forming an etch mask; the etching of the semiconductor substrate forming first trenches (231) in the semiconductor substrate defining the first fin (233) between the first trenches in the first region (a), and second trenches (232) in the semiconductor substrate defining the second fin (234) between the second trenches in the fourth region (b-2).

The fourth thickness (e4) is smaller than the third thickness (e3); and/or the fourth thickness (e4) is smaller than half the first distance (D1); and/or the third thickness (e3) is greater than or equal to half the second distance (D1); and/or the first distance (D1) is substantially equal to the second distance (D1).

The first thickness (e8) is smaller than or equal to 15 nm and the second thickness (e9) is greater than or equal to 30 nm; and/or the first length (L1; L3) is smaller than or equal to 30 nm and the second length (L2; L4) is greater than or equal to 150 nm.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of manufacturing an electronic device comprising:
forming first fin field-effect transistors in a first region of a first surface of a semiconductor substrate, and at least one second field-effect transistor with a metal-oxide-semiconductor structure in at least one second region of the first surface, the forming the first fin field-effect transistors and the at least one second field-effect transistor including: forming, in the first region, a plurality of first sacrificial gates of a first length along a first fin of the semiconductor substrate, the first length extending along a first direction, the first fin having a first width at the first surface of the semiconductor substrate and being isolated by first trenches in the semiconductor substrate;
forming, in each second region, a second sacrificial gate of a second length along the first direction greater than the first length at the first surface of the semiconductor substrate, the first and second sacrificial gates including a sacrificial material, the forming the first and second sacrificial gates including:
forming first spacers of a first thickness on flanks of the first sacrificial gates; and
forming second spacers of a second thickness greater than the first thickness on flanks of the second sacrificial gate, the second spacers including:
a plurality of L-shaped dielectric layers, each having a first portion on a sidewall of the second sacrificial gate and a second portion transverse to the first portion and on the first surface of the semiconductor substrate; and
a plurality of rounded spacers, each being directly on both the first and second portions of a respective L-shaped dielectric layer;
forming, in the semiconductor substrate, first semiconductor regions in the first region on either side of the first sacrificial gates flanked by the first spacers along the first direction, the first semiconductor regions forming drain and source regions of the first transistors;
forming, in the semiconductor substrate, second semiconductor regions in each second region on either side of the second sacrificial gate flanked by the second spacers along the first direction, the second semiconductor regions forming drain and source regions of the at least one second transistor; and
replacing each first sacrificial gate with a first gate structure and each second sacrificial gate with a second gate structure.

2. The method according to claim 1, wherein the forming the first and second sacrificial gates includes:
forming, on the semiconductor substrate, a first portion of a first layer including the sacrificial material in the first region, and a second portion of the first layer in each second region, the first portion extending over substantially an entire length of the first region, and the second portion extending over the second length, shorter than the length of the second region, forming part of the second sacrificial gate; and
forming, on flanks of the first and second portions of the first layer, a stack of layers including a dielectric material,
wherein the stack of layers including the dielectric material on the flanks of the second portion of the first layer form the second spacers.

3. The method according to claim 2, wherein the forming of the stack of layers includes:
forming, on the flanks of the first portion of the first layer, respectively of the second portion of the first layer, and on the semiconductor substrate, a second layer made of a first dielectric material of a low permittivity material;
forming, on the second layer, a third layer made of a second dielectric material;
forming, by etching the second and third layers:
first and second L-shaped dielectric layers belonging to the plurality of L-shaped dielectric layers, the first and second L-shaped dielectric layers being formed from the second layer; and
first and second D-shaped portions on the first and second L-shaped dielectric layers, respectively, the first and second D-shaped portions being formed from the third layer; and
forming, on the first D-shaped portions, and second D-shaped portions, first and second portions, respectively, of a fourth layer including a third dielectric material.

4. The method according to claim 3, wherein the forming the first and second portions of the fourth layer includes forming, by a deposition and an etching of the fourth layer:
the first portions of the fourth layer on the first D-shaped portions;
third portions of the fourth layer on the first portion of the first layer, the third portions being arranged in a row and each extending over a length substantially equal to the first length;
the second portions of the fourth layer on the second D-shaped portions; and
a fourth portion of the fourth layer on the second portion of the first layer.

5. The method according to claim 4, comprising forming, via an etching of the first portion of the first layer, third portions of the first layer arranged in a row and each extending over a length substantially equal to the first length, forming at least part of the first sacrificial gates.

6. The method according to claim 5, wherein the etching the first portion of the first layer is performed through the third portions of the fourth layer forming an etch mask, the third portions of the first layer extending between the semiconductor substrate and the third portions of the fourth layer.

7. The method according to claim 5, wherein the forming the first and second spacers includes, after the forming the third portions of the first layer, forming first portions of a fifth layer of a fourth dielectric material on flanks of the first sacrificial gates, forming the first spacers, and forming second portions of the fifth layer on the flanks of each second sacrificial gate covered by the stack of layers, the second spacers including the second portions of the fifth layer.

8. The method according to claim 1, wherein the forming the second semiconductor regions is performed at a same time as the forming the first semiconductor regions.

9. The method according to claim 1, wherein the forming the second semiconductor regions is performed at a first time and the forming the first semiconductor regions is performed at a second time that is not equal to the first time.

10. The method according to claim 9, wherein a fifth layer includes a third portion extending on either side of the second sacrificial gate and of the second spacers in each second region, along the second direction, to the third portion of the fifth layer masking the semiconductor substrate in the second region during the forming the first semiconductor regions.

11. The method according to claim 1, comprising:
forming a second of the at least one second transistor on top and inside of a mesa flush with the first surface of the semiconductor substrate, in a second region of the at least one second region
forming a third of the at least one second transistor along a second fin of the semiconductor substrate, in a third region of the at least one second region, the second fin having a second width at the first surface of the semiconductor substrate, and being isolated by second trenches in the semiconductor substrate, the second width being greater than the first width.

12. The method according to claim 11, wherein the forming the first fin in the first region and the second fin in the third region of the at least one second region includes:
forming, on the first surface of the semiconductor substrate, first pillars in the first region and second pillars in the third region of the at least one second region, the first and second pillars being arranged side by side in a row, and including a first material, the first pillars being separated from one another by a first distance and the second pillars being separated from one another by a second distance;
forming, on the first and second pillars, a sixth layer including a second material, selectively etchable over the first material, the sixth layer having a third thickness on flanks of the first and second pillars;
removing the sixth layer in the first region, the sixth layer being kept on the flanks of the second pillars in the third region of the at least one second region;
forming, on the first and second pillars, a seventh layer including the second material, the seventh layer having a fourth thickness defined to form, on the flanks of the first pillars, first posts separated from one another between the first pillars;
forming, via the sixth and seventh layers on the flanks of the second pillars, second posts;
removing the first and second pillars;
forming an etching mask by etching the semiconductor substrate from the first surface through the first, second, and third posts; and
forming first trenches in the semiconductor substrate defining the first fin between the first trenches in the first region, and second trenches in the semiconductor substrate defining the second fin between the second trenches in the third region of the at least one second region, by etching the semiconductor substrate.

13. The method according to claim 2, further comprising:
before the forming the first portion and the second portion of the first layer, forming an etch stop layer on the semiconductor substrate, the etch stop layer including silicon dioxide and including:
first portions in the first region, the first portions being suppressed during the forming the first sacrificial gates and the first gate structure; and
second portions in the at least one second region, the second portions being maintained under the second spacer during forming the second sacrificial gates and the second gate structure.

14. An electronic device comprising,
first fin field-effect transistors in a first region of a semiconductor substrate, the first transistors each including a first gate structure of a first length along a first fin of the semiconductor substrate, the first fin having a first width at a first surface of the semiconductor substrate and being isolated by first trenches in the semiconductor substrate, each first gate structure being flanked by a first spacer having a first thickness; and
at least one second field-effect transistor of metal-oxide-semiconductor structure in at least one second region of the semiconductor substrate, the at least one second transistor including a second gate structure of a second length on the first surface of the semiconductor substrate, the second length being greater than the first length, each second gate structure being flanked by a second spacer having a second thickness greater than the first thickness, each second spacer including:
a plurality of L-shaped dielectric layers, each having a first portion on a sidewall of the second gate structure and a second portion transverse to the first portion and on the first surface of the semiconductor substrate; and
a plurality of rounded spacers, each being directly on both the first and second portions of a respective L-shaped dielectric layer.

15. The device according to claim 14, wherein a third transistor of the at least one second transistor is formed on top and inside of a mesa coplanar with the first surface of the semiconductor substrate, in a third region of the at least one second region.

16. The device according to claim 14, wherein a fourth transistor of the at least one second transistor is formed along a second fin of the semiconductor substrate, in a fourth region of the at least one second region, the second fin having a second width at the level of the first surface of the semiconductor substrate, and being isolated by second trenches in the semiconductor substrate, the second width being greater than the first width.

17. The device according to claim 14, wherein:
the first thickness is equal to, at largest, 15 nm and the second thickness is equal to, at smallest 30 nm.

18. The device according to claim 14, wherein each second transistor includes an insulating portion between the semiconductor substrate and the second spacer.

19. A method, comprising:
forming, along a first fin in a first region of a semiconductor substrate, a first plurality of gate structures, the first fin having a first width along a first direction and each first gate structure having a first length along the first direction;
forming, in a second region of the semiconductor substrate, a second gate structure having a second length along the first direction greater than the first length;
forming a spacer structure around the second gate structure, the spacer structure including:
a plurality of insulating portions on the semiconductor substrate, each insulating portion abutting the second gate structure;
a plurality of L-shaped dielectric layers, each having a first portion on a sidewall of the second gate structure and a second portion transverse to the first portion and on a respective insulating portion; and
a plurality of rounded spacers, each being directly on both the first and second portions of a respective L-shaped dielectric layer;
forming first, doped semiconductor regions in the first region of the semiconductor substrate on opposite sides of each first gate structure along the second direction; and
forming second, doped semiconductor regions in the second region of the semiconductor substrate on opposite sides of the second gate structure along the second direction.

20. The method according to claim 18, wherein the first doped semiconductor regions and the first plurality of gate structures collectively form a first plurality of transistors and the second doped semiconductor regions and the second gate structure collectively form a second transistor.
